(19) United States
(12) Patent Application Publication
(10) Pub. No.: US 2019/0312228 A1
(43) Pub. Date: Oct. 10, 2019

(54) MANUFACTURING METHOD OF ELECTRO-OPTICAL DEVICE AND ELECTRO-OPTICAL DEVICE

(71) Applicant: Sharp Kabushiki Kaisha, Sakai City, Osaka (JP)

(72) Inventors: Tohru SONODA, Sakai City (JP); Hisao OCHI, Sakai City (JP); Jumpei TAKAHASHI, Sakai City (JP); Tohru SENOO, Sakai City (JP); Takeshi HIRASE, Sakai City (JP); Takashi OCHI, Sakai City (JP); Akihiro MATSUI, Sakai City (JP); Yoshinobu MIYAMOTO, Sakai City (JP)

(21) Appl. No.: 16/468,702

(22) PCT Filed: Jul. 14, 2017
(86) PCT No.: PCT/JP2017/025647

§ 371 Date: Jun. 12, 2019

(51) Int. Cl. H01L 51/52; H01L 51/56

(52) U.S. Cl. CPC H01L 51/5253; H01L 51/56

(57) ABSTRACT

A first protruding portion that has a surface having liquid-philic properties to an ink material and has a frame shape and a second protruding portion that has a surface having liquid-repellent properties to the ink material, surrounds the first protruding portion such that at least a part of the first protruding portion is located inside, and has a frame shape are formed so as to surround an electro-optical element. Then, the ink material is applied to a region surrounded by the first protruding portion and is cured, and thus an organic layer that seals the electro-optical element is formed.

### TECHNICAL FIELD

The disclosure relates to a manufacturing method of an electro-optical device and an electro-optical device.

### BACKGROUND ART

An electro-optical element, such as an organic EL element, using electroluminescence (hereinafter described as “EL”) of a luminescent material is generally easily affected by moisture, oxygen, and the like. When the electro-optical element reacts with a minute quantity of moisture and oxygen, its characteristics deteriorate, which causes a decrease in reliability and reduced lifetime of a display device.

A method for sealing an electro-optical element with a sealing film including an organic layer made of resin is known as a method for preventing infiltration of moisture and oxygen into the electro-optical element.

However, resin is liquid and has a wet-spreading characteristic. Thus, PTL 1 discloses that, for example, in an organic EL panel including an organic EL element formed of an organic film including a light-emitting layer, a flow of resin that seals the organic EL element is stopped by forming a plurality of protruding portions surrounding the organic EL element in many layers.

The protruding portion is formed by patterning an insulating layer constituting a bank that partitions the organic EL element. A surface of the protruding portion is covered with a protection film. A protruding portion corresponding to a shape of the insulating layer is formed on a surface of the protection film. In PTL 1, a flow of the resin is stopped with the protruding portion on the surface of the protection film by providing the resin on the protection film.

### CITATION LIST

### Patent Literature

PTL 1: JP 2012-3989 A (published on Jan. 5, 2012)

### SUMMARY

### Technical Problem

However, when a flow of the resin cannot be stopped even with the protruding portion at a panel end portion and the resin climbs over the protruding portion of the panel end portion, an end portion of the organic layer to be obtained is exposed. Then, moisture enters the panel through the organic layer, which damages the organic EL element and reduces reliability of the organic EL panel.

In PTL 1 described above, the plurality of protruding portions in many layers surround the organic EL element to hold back a flow of the resin. Thus, frame narrowing cannot be achieved.

The disclosure has been made in view of the problem described above, and an object thereof is to provide a manufacturing method of an electro-optical device capable of obtaining an electro-optical device that has higher properties of holding back a liquid organic material used for an organic layer sealing an electro-optical element than those of the related art, can achieve frame narrowing, and has a high degree of reliability, and to provide such an electro-optical device.

### Solution to Problem

To solve the problem described above, a manufacturing method of an electro-optical device according to one aspect of the disclosure is a manufacturing method of an electro-optical device including at least one electro-optical element and a sealing film, the sealing film sealing the electro-optical element on a support body, the sealing film including an organic layer obtained by curing an ink material, a first inorganic layer, and a second inorganic layer, the first inorganic layer and the second inorganic layer sandwiching the organic layer. The manufacturing method includes: a liquid-philic protruding portion formation step for forming a liquid-philic protruding portion, the liquid-philic protruding portion having a surface having liquid-philic properties to the ink material, the liquid-philic protruding portion having a frame shape, the liquid-philic protruding portion surrounding the electro-optical element; a liquid-repellent protruding portion formation step for forming a liquid-repellent protruding portion, the liquid-repellent protruding portion having a surface having liquid-repellent properties to the ink material, the liquid-repellent protruding portion having a frame shape, the liquid-repellent protruding portion surrounding the liquid-philic protruding portion, at least a part of the liquid-philic protruding portion being located inside the liquid-repellent protruding portion; and an organic layer formation step for applying the ink material to a region surrounded by the liquid-philic protruding portion and then curing the ink material and forming the organic layer.

To solve the problem described above, an electro-optical device according to one aspect of the disclosure is an electro-optical device including at least one electro-optical element and a sealing film, the sealing film sealing the electro-optical element on a support body, the sealing film including an organic layer obtained by curing an ink material, a first inorganic layer, and a second inorganic layer, the first inorganic layer and the second inorganic layer sandwiching the organic layer. The electro-optical device includes: a plurality of protruding portions surrounding the organic layer and having a frame shape. The protruding portions include a liquid-philic protruding portion having a surface having liquid-philic properties to the ink material and a liquid-repellent protruding portion having a surface having liquid-repellent properties to the ink material. The liquid-repellent protruding portion surrounds the liquid-philic protruding portion, at least a part of the liquid-philic protruding portion being located inside the liquid-repellent protruding portion.

### Advantageous Effects of Disclosure

The disclosure can provide a manufacturing method of an electro-optical device capable of obtaining an electro-optical device that has higher properties of holding back a liquid organic material used for an organic layer sealing an electro-optical element than those of the related art, can achieve frame narrowing, and has a high degree of reliability, and provide such an electro-optical device.

### BRIEF DESCRIPTION OF DRAWINGS

FIG. 1 is a cross-sectional view schematically illustrating a schematic configuration of main portions of an electro-optical device according to a first embodiment of the disclosure.

FIG. 2 is a plan view schematically illustrating a schematic configuration of the main portions of the electro-optical device according to the first embodiment of the disclosure.

FIG. 3 is a cross-sectional view illustrating one example of a schematic configuration of the main portions of the electro-optical device according to the first embodiment of the disclosure.

(a) to (d) of FIG. 4 are cross-sectional views illustrating a manufacturing method of an electro-optical device according to the first embodiment of the disclosure in order of steps.

FIG. 5 is a cross-sectional view illustrating a structure of a damming portion in a known electro-optical device.

FIG. 6 is a cross-sectional view illustrating a structure of a damming portion when a liquid-repellent bank is provided on a first inorganic layer.

FIG. 7 is a cross-sectional view schematically illustrating a schematic configuration of main portions of an electro-optical device according to a second embodiment of the disclosure.

(a) to (d) of FIG. 8 are cross-sectional views illustrating a manufacturing method of an electro-optical device according to the second embodiment of the disclosure in order of steps.

FIG. 9 is a cross-sectional view schematically illustrating a schematic configuration of main portions of an electro-optical device according to a third embodiment of the disclosure.

FIG. 10 is a plan view schematically illustrating a schematic configuration of the main portions of the electro-optical device according to the third embodiment of the disclosure.

(a) to (d) of FIG. 11 are cross-sectional views illustrating a manufacturing method of an electro-optical device according to the third embodiment of the disclosure in order of steps.

FIG. 12 is a cross-sectional view schematically illustrating a schematic configuration of main portions of an electro-optical device according to a fourth embodiment of the disclosure.

(a) to (e) of FIG. 13 are cross-sectional views illustrating a manufacturing method of an electro-optical device according to the fourth embodiment of the disclosure in order of steps.

FIG. 14 is a cross-sectional view schematically illustrating a schematic configuration of main portions of an electro-optical device according to a fifth embodiment of the disclosure.

(a) to (d) of FIG. 15 are cross-sectional views illustrating a manufacturing method of an electro-optical device according to the fifth embodiment of the disclosure in order of steps.

### DESCRIPTION OF EMBODIMENTS

A detailed description follows regarding embodiments of the disclosure.

### First Embodiment

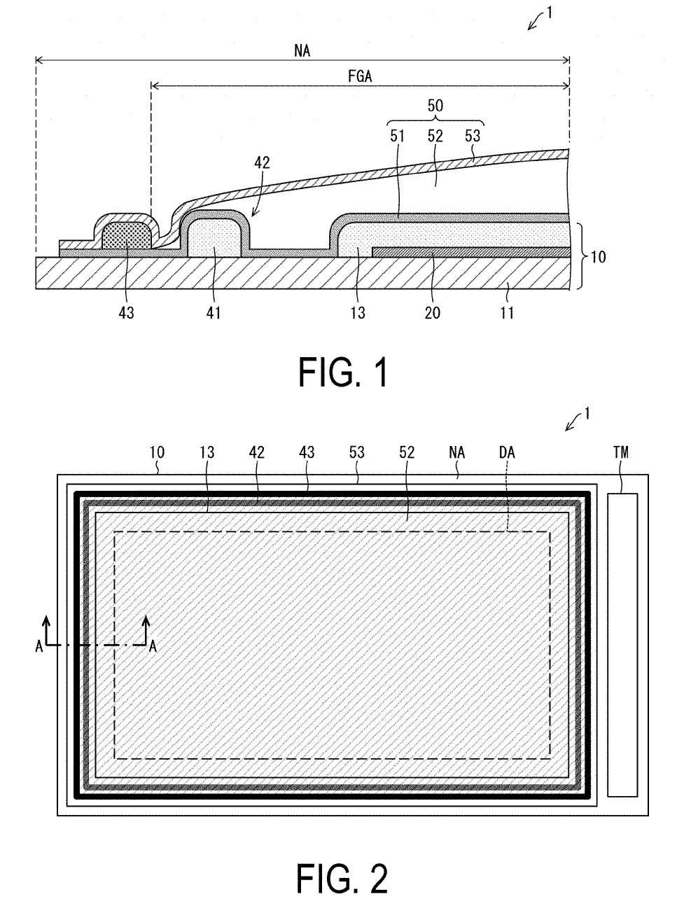

A description follows regarding one aspect of the disclosure, on the basis of FIGS. 1 to 6.

### Schematic Configuration of Electro-Optical Device

FIG. 1 is a cross-sectional view schematically illustrating a schematic configuration of main portions of an electro-optical device 1 according to the present embodiment. FIG. 2 is a plan view schematically illustrating a schematic configuration of the main portions of the electro-optical device 1 according to the present embodiment.

As illustrated in FIG. 2, in the electro-optical device 1 according to the present embodiment, a second protruding portion 43 surrounds a first protruding portion 42 such that the second protruding portion 43 is located outside the first protruding portion 42. An organic layer 52 is provided inside the first protruding portion 42 and inside the second protruding portion 43. As illustrated in FIG. 1, the first protruding portion 42 has a configuration in which a first bank 41 is covered with a first inorganic layer 51. Details are described below.

As illustrated in FIG. 1, the electro-optical device 1 according to the present embodiment includes a circuit substrate 10 (support body), an electro-optical element layer (not illustrated) that is provided on the circuit substrate 10 and includes an electro-optical element (not illustrated), the first bank 41, the second protruding portion 43 being a second bank, and a sealing film 50. Note that, a cover body (not illustrated) may be provided on the sealing film 50 with an adhesive layer (not illustrated), for example, interposed therebetween.

The circuit substrate 10 has a configuration in which a driving element (not illustrated) that drives the electro-optical element and a plurality of wiring lines (not illustrated) are provided as a circuit portion 20 driving the electro-optical element on a base 11 having insulating properties. Note that, an inorganic insulating layer (not illustrated) that protects the driving element and the wiring lines in the circuit portion 20 may be provided on the base 11. The circuit substrate 10 further suitably includes a flattened layer 13 (interlayer insulating film) that covers the circuit portion 20. The electro-optical element layer (electro-optical element unit) including the electro-optical element is suitably provided on the flattened layer 13.

The electro-optical element is covered with the sealing film 50 that seals the electro-optical element. The sealing film 50 includes the first inorganic layer 51 (lower layer inorganic sealing layer, first inorganic sealing layer), the organic layer 52 (organic sealing layer) formed by curing an ink material, and a second inorganic layer 53 (upper layer inorganic sealing layer, second inorganic sealing layer).

As illustrated in FIG. 1 and FIG. 2, the first bank 41 surrounding the organic layer 52 is provided outside the flattened layer 13 provided with the electro-optical element. As illustrated in FIG. 1, the first bank 41 is covered with the first inorganic layer 51. The first inorganic layer 51 has a shape that follows a shape of a layer being an underlayer thereof. The first inorganic layer 51 on the first bank 41 has a protruding shape that follows a shape of the first bank 41. Thus, the flattened layer 13 is surrounded by the first bank 41 that is covered with the first inorganic layer 51 and serves as the first protruding portion 42.

A surface of the first inorganic layer 51 has liquid-philic properties to an ink material (inkjet application liquid) being a liquid organic material used for the organic layer 52. Thus, the first protruding portion 42 functions as a liquid-philic protruding portion having liquid-philic properties to the ink material used for the organic layer 52.

The second bank surrounding the first protruding portion 42 is provided as the second protruding portion 43 outside the first protruding portion 42.

The second protruding portion 43 formed of the second bank is formed on the first inorganic layer 51. The second protruding portion 43 functions as a liquid-repellent protruding portion having liquid-repellent properties to the ink material used for the organic layer 52.

Although it is not illustrated, a contact angle θ of the ink material with respect to the first protruding portion 42 is θ<5 degrees, and a contact angle θ of the ink material with respect to the second protruding portion 43 is θ>60 degrees. The contact angle θ represents, when a solid surface contacts liquid and gas, an angle between a liquid surface and the solid surface in a boundary in which the three phases contact each other. Given that a surface tension (interface energy) between solid and liquid is γSL, a surface tension between liquid and gas is γLG, and a surface tension between solid and gas is γSG, the contact angle θ is determined by cos θ=(γSG−γSL)/γLG by Young's rule from a balance in a component of the surface tension between the interfaces. It may be defined as liquid-philic when the contact angle θ is θ<90 degrees with respect to water and defined as liquid-repellent when the contact angle θ is θ>90 degrees.

The organic layer 52 is formed inside the first protruding portion 42 (that is, within a region surrounded by the first protruding portion 42) and inside the second protruding portion 43 (that is, within a region surrounded by the second protruding portion 43) in a plan view. The first protruding portion 42, the second protruding portion 43, and the organic layer 52 are covered with the second inorganic layer 53.

The electro-optical device 1 according to the present embodiment may be a flexible device that has flexibility and can be bent, or may be a rigid device that has rigidity and cannot be bent.

### Specific Example

Hereinafter, the electro-optical device 1 will be described by taking a specific example.

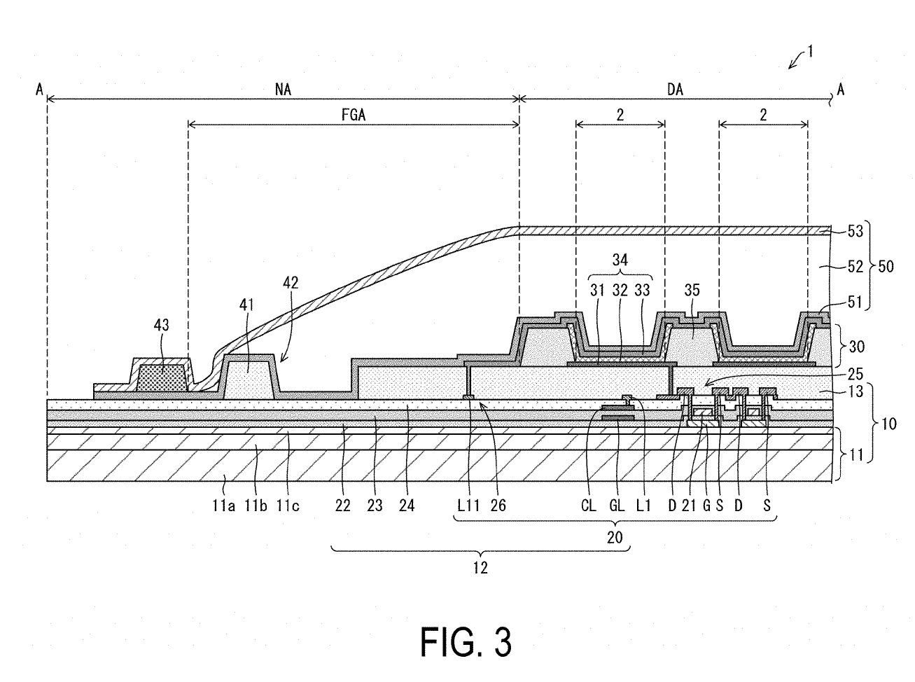

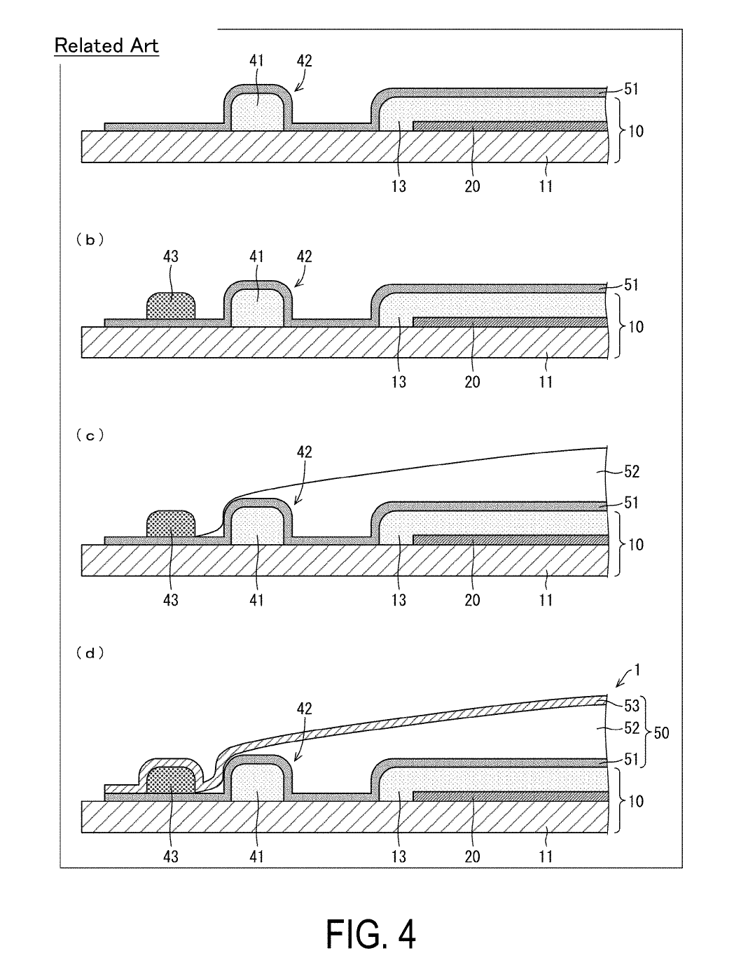

FIG. 3 is a cross-sectional view illustrating one example of a schematic configuration of the main portions of the electro-optical device 1 according to the present embodiment. Note that, FIG. 3 corresponds to a cross-sectional view seen in the direction of arrows on a line A-A of the electro-optical device 1 illustrated in FIG. 2.

FIG. 3 illustrates, as an example, that the electro-optical device 1 according to the present embodiment is an organic EL display device provided with an Organic Light Emitting Diode (OLED) element 34, known as an organic EL element, as an electro-optical element.

The electro-optical device 1 illustrated in FIG. 3 includes, for example, a Thin Film Transistor (TFT) substrate as the circuit substrate 10 and also includes an OLED element layer 30 (OLED element portion) as the electro-optical element layer.

### Circuit Substrate 10

The circuit substrate 10 illustrated in FIG. 3 includes the base 11 having insulating properties, a TFT layer 12 provided on the base 11, and the flattened layer 13 (interlayer insulating film) that covers the circuit portion 20 in the TFT layer 12.

As illustrated in FIG. 3, for example, the base 11 may be a layered film including a lower face film 11a, a resin layer 11b, and a barrier layer 11c (moisture-proof layer) provided in this order, or may be a glass substrate, a plastic substrate, or a plastic film.

Examples of resin used for the resin layer 11b, the plastic substrate, or the plastic film include a polyimide, polyethylene naphthalate, a polyamide and the like.

The barrier layer 11c is a layer for preventing moisture and impurities from reaching the TFT layer 12 or the OLED element layer 30. The barrier layer 11c is provided over the whole surface of the resin layer 11b, such that the surface of the resin layer 11b is not exposed. The barrier layer 11c can be formed of, for example, a silicon nitride (SiNx) film, a silicon oxide (SiOx) film, or a layered film thereof formed using Chemical Vapor Deposition (CVD).

When the electro-optical device 1 is a flexible device, the lower face film 11a is bonded to a lower face of the resin layer 11b with an adhesive layer (not illustrated), for example, interposed therebetween and thus, even when the resin layer 11b is extremely thin, the lower face film 11a is used for manufacturing the electro-optical device 1 having sufficient strength. A plastic film formed from a flexible resin is used as the lower face film 11a. Examples of the flexible resin include polyethylene terephthalate, polyethylene naphthalate, a polyimide, a polycarbonate, and polyethylene.

The TFT layer 12 is a circuit layer including the circuit portion 20 in which a TFT 25 (driving element) that drives the electro-optical element (OLED element 34 in the example illustrated in FIG. 3) and a plurality of wiring lines are formed, and inorganic insulating layers 22, 23, and 24 that protect the wiring lines and electrodes (gate electrode G, source electrode S, and drain electrode D) in the TFT 25 in the circuit portion 20.

The wiring lines include, for example, wiring lines such as a plurality of gate wiring lines GL, a plurality of source wiring lines (not illustrated), a plurality of capacitance wiring lines CL, a plurality of high level power source lines L1, a plurality of low level power source lines (not illustrated), and a plurality of second electrode connecting wiring lines L11. The inorganic insulating layers 22, 23, and 24 are formed so as to cover the whole surface of the base 11.

The TFT layer 12 has a configuration in which a semiconductor layer 21 formed into a plurality of island shapes, the inorganic insulating layer 22 (gate insulating film), a first wiring line layer, the inorganic insulating layer 23 (first passivation film), a second wiring line layer, the inorganic insulating layer 24 (second passivation film), and a third wiring line layer are laminated in this order. An end portion of the TFT layer 12 is provided with a terminal portion TM (see FIG. 2) including a plurality of terminals (terminal electrodes) for external connection.

The first wiring line layer includes, for example, the plurality of gate electrodes G, the plurality of gate wiring lines GL connected to the plurality of gate electrodes G, and the plurality of low level power source lines (not illustrated). The second wiring line layer includes, for example, the plurality of capacitance wiring lines CL. The third wiring line layer includes, for example, the plurality of source electrodes S, the plurality of source wiring lines (not illustrated) connected to the plurality of source electrodes S, the plurality of drain electrodes D, the plurality of high level power source lines L1, and the plurality of second electrode connecting wiring lines L11 connected to a second electrode 33 of the OLED element 34. The gate wiring line GL and the source wiring line are intersected orthogonal to each other in the plan view.

The flattened layer 13 is provided on the TFT layer 12 so as to cover the third wiring line layer. In this way, the flattened layer 13 levels a step on the TFT 25 and the third wiring line layer.

The semiconductor layer 21, the gate electrode G, the inorganic insulating layer 22, the source electrode S, and the drain electrode D constitute the TFT 25.

The source electrode S and the drain electrode D are each connected to the semiconductor layer 21 with a contact hole provided in the inorganic insulating layers 22, 23, and 24 interposed therebetween. The source electrode S is also connected to a source wiring line, which is not illustrated. The drain electrode D is connected to a first electrode 31 of the OLED element 34 with a contact hole provided in the flattened layer 13 interposed therebetween. The capacitance wiring line CL is connected to the high level power source line L1 with a contact hole provided in the inorganic insulating layer 24 interposed therebetween.

Note that, FIG. 3 illustrates, as an example, that the TFT 25 has a top gate structure. However, the TFT 25 may have a bottom gate structure.

The electro-optical device 1 includes an active region DA (region overlapping the electro-optical element layer in the plan view) provided with the electro-optical element and a non-active region NA (frame region, region that does not overlap the electro-optical element layer in the plan view) being a peripheral region surrounding the periphery of the active region DA.

In the electro-optical device 1 illustrated in FIG. 3, the active region DA is a region (region overlapping the OLED element layer 30) provided with the OLED element 34 and a pixel region provided with a plurality of pixels 2. The non-active region NA is a region that does not overlap the OLED element layer 30. The active region DA is used as a display region.

As illustrated in FIG. 2 and FIG. 3, the circuit portion 20 and the flattened layer 13 are provided from the active region DA to the non-active region NA. As illustrated in FIG. 2, the terminal portion TM is provided in a part of the non-active region NA. The gate wiring line GL and the source wiring line are each connected to a terminal (not illustrated) in the terminal portion TM via a lead wiring line (not illustrated). The non-active region NA is provided with the lead-out wiring line, a second electrode connecting portion 26 that connects the second electrode connecting wiring line L11 to the second electrode 33 extending from the active region DA, and the like. Note that, a source wiring line may be used as the second electrode connecting wiring line L11.

The semiconductor layer 21 is formed of, for example, low temperature polysilicon (LTPS) or an oxide semiconductor. The inorganic insulating layer 22 can be formed of, for example, a silicon oxide (SiOx) film or a silicon nitride (SiNx) film, or a layered film thereof, formed by CVD. The first wiring line layer, the second wiring line layer, the third wiring line layer, and the terminal portion TM are each formed of a single-layer film or a layered film of metal such as aluminum (Al), tungsten (W), molybdenum (Mo), tantalum (Ta), chromium (Cr), titanium (Ti), and copper (Cu), as one example. The flattened layer 13 can be made of a photosensitive resin such as polyimide resin and acrylic resin, for example.

### OLED Element Layer 30

As illustrated in FIG. 3, the OLED element layer 30 includes the first electrode 31 (lower electrode), an organic EL layer 32 (function layer) formed on the first electrode 31 and formed of an organic layer including at least a light-emitting layer, the second electrode 33 (upper electrode) formed on the organic EL layer 32, and an edge cover 35.

The first electrode 31, the organic EL layer 32, and the second electrode 33 constitute the OLED element 34 (light emitting element) constituting each of the pixels 2. Layers between the first electrode 31 and the second electrode 33 are collectively referred to as the organic EL layer 32 in the present embodiment.

The first electrode 31 is formed on the flattened layer 13 in the active region DA. The first electrode 31 injects (supplies) holes into the organic EL layer 32, while the second electrode 33 injects electrons into the organic EL layer 32.

The first electrode 31 is a pattern electrode (for example, a pattern anode electrode) formed in an island-shaped pattern for each of the pixels 2. Meanwhile, the second electrode 33 is a solid-like common electrode (for example, a common cathode electrode) provided in common to each of the pixels 2.

The first electrode 31 is electrically connected to the TFT 25 with a contact hole formed in the flattened layer 13 in each of the pixels 2 interposed therebetween. The second electrode 33 is electrically connected to the second electrode connecting wiring line L11 in the second electrode connecting portion 26.

The edge cover 35 is provided in, for example, a lattice pattern in the plan view so as to cover a peripheral portion (namely, each edge portion) of the first electrode 31. The edge cover 35 prevents a short-circuit with the second electrode 33 due to a concentration of electrodes, the thinned organic EL layer 32, or the like at the peripheral portion of the first electrode 31. The edge cover 35 also functions as a pixel separation layer (element molecule layer) that separates the pixels 2 (OLED elements 34) so as to prevent a current from leaking to the neighboring pixel 2 (OLED element 34). A photosensitive resin may be used for the edge cover 35.

For example, a transparent conductive film such as indium tin oxide (ITO) and indium zinc oxide (IZO) or a metal thin film such as gold (Au), platinum (Pt), and nickel (Ni) is used for the first electrode 31. At this time, to inject electrons into the light emitting layer, a metal with a small work function, such as lithium (Li), cerium (Ce), barium (Ba), and aluminum (Al), or an alloy containing these metals, such as a magnesium alloy (MgAg or the like), an aluminum alloy (AlLi, AlCa, AlMg or the like) is used for the second electrode 33.

### First Protruding Portion 42 and Second Protruding Portion 43

As illustrated in FIG. 1 to FIG. 3, the non-active region NA includes the first protruding portion 42 and the second protruding portion 43 such that the first protruding portion 42 and the second protruding portion 43 surround the flattened layer 13 provided with the OLED element 34, and is provided with a damming portion that holds back the ink material used for the organic layer 52 by stopping a flow of the ink material.

The first protruding portion 42 is formed in a frame shape formed of a continuous line so as to surround the flattened layer 13 provided with the OLED element 34. The second protruding portion 43 is formed in a frame shape formed of a continuous line so as to surround the first bank 41 outside the first protruding portion 42.

The first protruding portion 42 and the second protruding portion 43 are organic layer stoppers that define an edge of the organic layer 52 by holding back the ink material used for the organic layer 52 (in other words, by holding back the organic layer 52).

As described above, the first protruding portion 42 functions as a liquid-philic protruding portion, and the second protruding portion 43 functions as a liquid-repellent protruding portion. The first protruding portion 42 may have a surface having liquid-philic properties to the ink material. The second protruding portion 43 may have a surface having liquid-repellent properties to the ink material.

As described above, the first protruding portion 42 according to the present embodiment is formed of the first bank 41 covered with the first inorganic layer 51 having a surface having liquid-philic properties to the ink material. The first inorganic layer 51 may include a liquid-philic layer made of a material having liquid-philic properties to the ink material, and may have liquid-philic properties to the ink material by performing liquid-philic processing on the surface of the first inorganic layer 51.

Although a material for the first bank 41 is not particularly limited, the same material as that for the flattened layer 13 or the same material as that for the edge cover 35 may be used, for example. In this way, the first bank 41 can be formed simultaneously with the flattened layer 13 or the edge cover 35.

Examples of the material having liquid-philic properties to the ink material include an inorganic oxide such as silicon oxide (SiOx). Examples of the liquid-philic processing include atmospheric pressure plasma processing, oxygen plasma processing, hydrogen plasma processing, UV irradiation processing, exposure processing with ozone containing gas, and the like.

The second protruding portion 43 is formed of the second bank having a surface having liquid-repellent properties to the ink material. The second protruding portion 43 may be formed of the second bank made of a material having liquid-repellent properties to the ink material, and may have liquid-repellent properties to the ink material by performing liquid-repellent processing on the surface of the second bank.

Examples of the material having liquid-repellent properties to the ink material include a resin composition formed by mixing resin, such as acrylic resin and polyimide, with a fluorine-based additive, such as OPTOOL series of Daikin Industries, Ltd. and Surflon of AGC SEIMI CHEMICAL CO., LTD. Examples of the liquid-repellent processing include a method for applying a material having liquid-repellent properties to the ink material such as the resin composition to the surface of the second bank and a method for performing fluorine plasma processing using fluorine gas such as CF4, CHF3, and SF6 on the surface of the second bank.

### Sealing Film 50

The sealing film 50 includes the organic layer 52, and the first inorganic layer 51 and the second inorganic layer 53 that sandwich the organic layer 52. The first inorganic layer 51 and the second inorganic layer 53 are provided to overlap each other in the plan view so as to seal the organic layer 52 therebetween.

The first inorganic layer 51 and the second inorganic layer 53 have a moisture-proof function to inhibit the infiltration of moisture, and function as barrier layers to inhibit deterioration of the electro-optical element (OLED element 34 in the example illustrated in FIG. 3) caused by moisture or oxygen.

The organic layer 52 is used as a buffer layer (stress relief layer), which relieves stress in the first inorganic layer 51 and the second inorganic layer 53 in which film stress is large, performs leveling and filling of pinholes by burying step portions and foreign material on the surface of the OLED element layer 30 being the electro-optical element layer, and further, prevents the occurrence of cracks in the second inorganic layer 53 when the second inorganic layer 53 is layered, by leveling an underlayer of the second inorganic layer 53.

The first inorganic layer 51 and the second inorganic layer 53 are each formed by CVD, for example, and each can be configured by a silicon oxide film, a silicon nitride film, or a silicon oxynitride film, or by a layered film of these films.

The organic layer 52 is a light-transmissive organic insulating film thicker than the first inorganic layer 51 and the second inorganic layer 53. The organic layer 52 is formed by, for example, applying the ink material (liquid organic material) to a region surrounded by the first protruding portion 42 on the first inorganic layer 51 using an ink-jet method and the like, and curing the ink material with UV. Examples of the organic material include a photosensitive resin, such as an acrylic resin, an epoxy resin, and a silicon resin.

Note that, a cover body (not illustrated) may be provided on the sealing film 50 with an adhesive layer (not illustrated) interposed therebetween.

The cover body is a function layer having at least one of a protection function, an optical compensation function, and a touch sensor function. The cover body may be a protection film that functions as a support body when a carrier substrate such as a glass substrate is peeled, a hard coat layer such as a hard coat film, or a functional film such as a polarizing film and a touch sensor film.

### Manufacturing Method of Electro-optical Device 1

Next, with reference to FIG. 1 and (a) to (d) of FIG. 4, a manufacturing method of the electro-optical device 1 will be described below. (a) to (d) of FIG. 4 are cross-sectional views illustrating the manufacturing method of the electro-optical device 1 in order of steps.

First, as illustrated in FIG. 1 and (a) of FIG. 4, the circuit substrate 10 is formed by a publicly known method (circuit substrate formation step). Specifically, as illustrated in FIG. 3, for example, the TFT layer 12 including the circuit portion 20 including the TFT 25 and the plurality of wiring lines is formed as a driving element layer (driving element portion) on the base 11 by a publicly known method. Subsequently, a photosensitive resin is applied to the TFT layer 12 by a publicly known method, and patterning of the photosensitive resin is performed by photolithography and the like.

Note that, when the electro-optical device 1 is a flexible device at this time, the resin layer 11b and the barrier layer 11c are first film-formed in this order on a transparent carrier substrate (not illustrated) such as a glass substrate (for example, a mother glass). Subsequently, the TFT layer 12, the flattened layer 13, and the edge cover 35 are formed in order on the barrier layer 11c as described above.

The first bank 41 can be formed by patterning the photosensitive resin. The first bank 41 can be formed on the same plane as the flattened layer 13 simultaneously with the flattened layer 13 in the circuit substrate formation step by using the same material as that for the flattened layer 13 as a material for the first bank 41.

As one example, in the present embodiment, as illustrated in FIG. 1 to (a) of FIG. 4, the circuit substrate 10, such as a TFT substrate, in which the flattened layer 13 covering the circuit portion 20 is formed is formed on the base 11, and, at the same time, the first bank 41 having a frame shape and surrounding the flattened layer 13 is formed on the circuit substrate 10 (circuit substrate/first bank formation step).

A distance between the flattened layer 13 and the first bank 41 (namely, a distance between an outer peripheral surface of the flattened layer 13 and an inner peripheral surface of the first bank 41) is, for example, 50 μm, and is suitably set within a range of 15 μm to 100 μm. When the distance between the flattened layer 13 and the first bank 41 (in other words, a distance between the flattened layer 13 and the first protruding portion 42) is less than 15 μm, the organic layer 52 has a small thickness at an end portion of the flattened layer 13, and foreign matter may be insufficiently covered. When the distance between the flattened layer 13 and the first bank 41 exceeds 100 μm, a space portion between the flattened layer 13 and the first protruding portion 42 is large, and the ink material used for the organic layer 52 may flow into the space portion and stop on the way to the space portion without reaching the first protruding portion 42. Also, even when the ink material reaches the first protruding portion 42, the ink material may stop without reaching the second protruding portion 43. When the ink material stops on the way as described above, the organic layer 52 has a small thickness at the end portion of the flattened layer 13, and foreign matter may be insufficiently covered.

A thickness of the flattened layer 13 is set within a range of 0.5 μm to 5 μm, for example. Thus, a height of the first bank 41 is suitably set within a range of 0.5 μm to 5 μm. When the first bank 41 has a height of less than 0.5 μm, an effect of increasing a thickness of the organic layer 52 at the end portion of the flattened layer 13 as described later is not sufficiently obtained. When the first bank 41 has a height exceeding 5 μm, residual stress of the first inorganic layer 51 may concentrate at a bent portion formed by the first bank 41 and the base 11, and film peeling of the first inorganic layer 51 may occur.

Further, the ink material (liquid organic material) used for the organic layer 52 is likely to remain on a planar face, held back by the planar face, and kept for a while.

Thus, increasing an area of an upper face of the first bank 41 being a planar face is effective in order to hold back the ink material. To achieve this, increasing a width of the upper face of the first bank 41 is effective. On the other hand, as a width of the first bank 41 increases in the plan view, a width of the first protruding portion 42 increases in the plan view, and a width of the non-active region NA increases.

Note that, a width represents a length (line width) in a short-hand direction in the present embodiment and embodiments described later.

Therefore, a width of the upper face of the first bank 41 preferably falls within a range of 9 μm to 90 μm, for example.

Next, the electro-optical element layer including the electro-optical element is formed on the circuit substrate 10 (electro-optical element formation step).

Note that, the electro-optical element layer may be formed by a publicly known method according to a kind of the electro-optical element. For example, when the electro-optical element is the OLED element 34 and the electro-optical device 1 is a full-color organic EL display device, the first electrode 31 is first patterned and formed into a matrix shape on the flattened layer 13 by a publicly known method, such as sputtering, as illustrated in FIG. 3. Subsequently, an organic film (not illustrated) formed of, for example, a positive-working photosensitive resin such as an acrylic resin and a polyimide resin is film-formed on the circuit substrate 10 so as to cover the first electrode 31, and the edge cover 35 formed of the organic film is patterned and formed by photolithography and the like. Next, separately patterning vapor deposition is performed on the organic EL layer 32, for example, in association with each of the pixels 2 such that a light-emitting layer in each color covers a region surrounded by the edge cover 35. Note that, in the film formation of the organic EL layer 32, a method other than a vapor deposition method may be used, such as an ink-jet method and a printing method. Next, the second electrode 33 is formed on the entire active region DA in the circuit substrate 10 so as to cover the organic EL layer 32 and the edge cover 35, and is also electrically connected to the second electrode connecting wiring line L11 of the second electrode connecting portion 26. In this way, the OLED element layer 30 including the OLED element 34 can be formed as the electro-optical element layer on the circuit substrate 10.

The electro-optical element layer is sealed with the sealing film 50. A sealing film formation step includes a first inorganic layer formation step, an organic layer formation step, and a second inorganic layer formation step described later. Formation of the first protruding portion 42 (in other words, a liquid-philic protruding portion formation step) and formation of the second protruding portion 43 (in other words, a liquid-repellent protruding portion formation step) are performed during the sealing film formation step.

In the present embodiment, after formation of the electro-optical element, for example, a silicon nitride (SiNx) film and a silicon oxide (SiOx) film are first film-formed in this order as the first inorganic layer 51 in a region including the first bank 41 and the active region DA by CVD (first inorganic layer formation step).

A mask (not illustrated) having an opening in the region including the first bank 41 and the active region DA is used for film formation of the first inorganic layer 51. In other words, a mask (not illustrated) having an opening at least in a region surrounding the first bank 41 (more specifically, a region surrounding a region in which the second protruding portion 43 formed outside the first protruding portion 42 illustrated in FIG. 1 to FIG. 3 is to be formed) is used for film formation of the first inorganic layer 51. In this way, the first inorganic layer 51 that covers the electro-optical element layer and the first bank 41 is film-formed.

A thickness of the first inorganic layer 51 falls within a range of 0.5 μm to 3 μm, for example. A thickness of the silicon nitride film falls within a range of 0.4 μm to 2.98 μm, for example. A thickness of the silicon oxide film falls within a range of 0.02 μm to 0.1 μm, for example. In this way, since the first inorganic layer 51 is extremely thin, the first inorganic layer 51 has a shape that follows a shape of a layer being an underlayer thereof as described above.

The surface of the first bank 41 is covered with the first inorganic layer 51 having the silicon oxide film as the outermost surface. While not being exposed to the air, the silicon oxide film has liquid-philic properties to the ink material used for the organic layer 52. Thus, the silicon oxide film covering the surface of the first bank 41 maintains to be in a liquid-philic state to the organic material by performing steps (processing) from the first inorganic layer formation step to at least an organic layer formation step described later under vacuum (for example, in a vacuum chamber).

Note that, the surface of the silicon oxide film may be caused to be liquid-philic by performing atmospheric pressure plasma processing on the surface of the silicon oxide film after film formation of the silicon oxide film instead of performing the series of processing under vacuum. In a case where the surface of the silicon nitride film can be caused to be liquid-philic by performing atmospheric pressure plasma processing, the silicon oxide film does not need to be film-formed on the silicon nitride film. In other words, the liquid-philic silicon nitride film may be formed as the first inorganic layer 51 in the first inorganic layer formation step.

The first inorganic layer 51 on the first bank 41 has a protruding shape that follows a shape of the first bank 41. Thus, the first bank 41 covered with the first inorganic layer 51 functions as a liquid-philic protruding portion having liquid-philic properties to the ink material used for the organic layer 52.

According to the present embodiment, the first bank 41 is covered with the liquid-philic first inorganic layer 51 in such a manner, and thus the first protruding portion 42 being a liquid-philic protruding portion is formed (liquid-philic protruding portion formation step). In the present embodiment, as described above, the liquid-philic protruding portion may be formed simultaneously with the formation of the first inorganic layer 51, and the first protruding portion 42 may be formed by causing the first inorganic layer 51 to be liquid-philic after the formation of the first inorganic layer 51.

A height of the first protruding portion 42 preferably falls within a range of 1 μm to 8 μm. When the first protruding portion 42 has a height of less than 1.0 μm, an effect of increasing a thickness of the organic layer 52 at the end portion of the flattened layer 13 as described later is not sufficiently obtained. When the first protruding portion 42 has a height exceeding 8 μm, residual stress of the first inorganic layer 51 may concentrate at the bent portion formed by the first bank 41 and the base 11, and film peeling of the first inorganic layer 51 may occur. Herein, the base 11 serves as a reference for the height of the first protruding portion 42.

Next, as illustrated in FIG. 1 to FIG. 3 and (b) of FIG. 4, a liquid-repellent protruding portion formed of the second bank in a frame shape is formed as the second protruding portion 43 on the first inorganic layer 51 so as to surround the first protruding portion 42 (liquid-repellent protruding portion formation step).

The second protruding portion 43 can be formed by, for example, applying an application liquid having liquid-repellent properties to the ink material in a frame shape formed of a continuous line to the outside of the first protruding portion 42 by an ink-jet method or a printing method, and curing the application liquid with irradiation of UV (ultraviolet) light and the like.

A distance between the first protruding portion 42 and the second protruding portion 43 (distance between an outer peripheral surface of the first protruding portion 42 and an inner peripheral surface of the second protruding portion 43) preferably falls within a range of 7 μm to 99.5 μm. When the distance between the first protruding portion 42 and the second protruding portion 43 is less than 7 μm, the organic layer 52 has a small thickness at the end portion of the flattened layer 13, and foreign matter may be insufficiently covered. When the distance between the first protruding portion 42 and the second protruding portion 43 exceeds 99.5 μm, a space portion between the first protruding portion 42 and the second protruding portion 43 is large, and the ink material used for the organic layer 52 may flow into the space portion and stop on the way to the space portion without reaching the second protruding portion 43. When the ink material stops on the way as described above, the organic layer 52 has a small thickness at the end portion of the flattened layer 13, and foreign matter may be insufficiently covered.

A distance between an inner peripheral surface of the first protruding portion 42 and an outer peripheral surface of the second protruding portion 43 is, for example, 151 μm, and preferably falls within a range of 30.5 μm to 303 μm. When the distance between the inner peripheral surface of the first protruding portion 42 and the outer peripheral surface of the second protruding portion 43 is less than 30.5 μm, the ink material used for the organic layer 52 may climb over the second protruding portion 43 and overflow. When the distance between the inner peripheral surface of the first protruding portion 42 and the outer peripheral surface of the second protruding portion 43 exceeds 303 μm, a width of the non-active region NA increases.

A width of the second protruding portion 43 in the plan view preferably falls within a range of 10 μm to 100 μm. When the second protruding portion 43 has a width of less than 10 μm, formation of a shape of the second protruding portion 43 is insufficient due to small foreign matter and the like, and the second protruding portion 43 may not completely surround the active region DA and may be interrupted. Furthermore, when the second protruding portion 43 has a width of less than 10 μm, a contact area between the second protruding portion 43 and the first inorganic layer 51 is small, and film peeling of the second protruding portion 43 may occur. On the other hand, as a width of the second protruding portion 43 increases in the plan view, a width of the non-active region NA increases. Thus, a width of the second protruding portion 43 in the plan view is preferably set to be less than or equal to 100 μm.

A height of the second protruding portion 43 preferably falls within a range of 0.5 μm to 5 μm. When the second protruding portion 43 has a height of less than 0.5 μm, the ink material used for the organic layer 52 may climb over the second protruding portion 43 and overflow. When the second protruding portion 43 has a height exceeding 5 μm, residual stress of the second inorganic layer 53 may concentrate at a bent portion formed by the second protruding portion 43 and the base 11, and film peeling of the second inorganic layer 53 may occur.

Next, as illustrated in FIG. 1 to FIG. 3 and (c) of FIG. 4, the organic layer 52 is formed on the first inorganic layer 51 in the region surrounded by the first protruding portion 42 (organic layer formation step).

In the organic layer formation step, the ink material (application liquid) to be the organic layer 52 is first applied to the entire surface in the region that includes the active region DA and is surrounded by the first protruding portion 42 having a frame shape by an ink-jet method.

The ink material flows and wet-spreads while overlapping, and is then leveled in the active region DA, whereas the ink material has a film thickness gradually decreasing and most of the ink material is held back by the first protruding portion 42 in the non-active region NA. Hereinafter, a region in which the film thickness gradually decreases is referred to as a film thickness gradual decrease region FGA.

However, a part of the ink material climbs over the first protruding portion 42 due to high wettability of the first protruding portion 42 being the liquid-philic protruding portion. The ink material climbing over the first protruding portion 42 reaches the second protruding portion 43, but the ink material is reliably held back by the second protruding portion 43 because the second protruding portion 43 has high liquid-repellent properties to the ink material.

Next, the ink material is irradiated with UV light. In this way, the ink material is cured, and the organic layer 52 is formed.

A thickness of the organic layer 52 in the active region DA suitably falls within a range of 4 μm to 20 μm. A thickness of the organic layer 52 at the end portion of the flattened layer 13 in the film thickness gradual decrease region FGA suitably falls within a range of 3 μm to 16 μm. When a step is managed such that the size of foreign matter generated in a manufacturing step is suppressed to less than or equal to 3 μm, a thickness of the organic layer 52 needs to be at least greater than or equal to 3 μm in order to sufficiently cover the foreign matter.

Next, as illustrated in FIG. 1 to FIG. 3 and (d) of FIG. 4, for example, a silicon nitride (SiNx) film is film-formed as the second inorganic layer 53 in a region including the second protruding portion 43 and the active region DA by CVD (second inorganic layer formation step).

A mask (not illustrated) having an opening in the region surrounding the second protruding portion 43 is used for the film formation of the second inorganic layer 53. A mask having the same shape as that of the mask used for the film formation of the first inorganic layer 51 may be used as the mask. In this way, the second inorganic layer 53 overlapping the first inorganic layer 51 can be film-formed. A thickness of the second inorganic layer 53 falls within a range of 0.5 μm to 3 μm, for example. The second inorganic layer 53 suppresses infiltration of moisture and oxygen from the outside and damage to the OLED element 34. The second inorganic layer 53 desirably has a thickness of greater than or equal to 0.5 μm to obtain sufficient properties of blocking moisture and oxygen. Further, the whole stress increases with a thicker second inorganic layer 53. Thus, when the second inorganic layer 53 becomes too thick, film peeling of the second inorganic layer 53 may be induced. Therefore, the second inorganic layer 53 desirably has a thickness of less than or equal to 3 μm.

In this way, the sealing film 50 formed of the first inorganic layer 51, the organic layer 52, and the second inorganic layer 53 is formed. Note that, when the electro-optical device 1 is a flexible device, a protection film or the like is bonded to the sealing film 50 after the sealing film step, and the above-mentioned carrier substrate is peeled by ablation by laser irradiation at an interface between the carrier substrate and the resin layer 11b. Subsequently, the lower face film 11a is bonded to a peeling face of the carrier substrate, and singulation of the electro-optical device 1 is then performed as necessary.

After that, as necessary, a functional film, such as a polarizing film and a touch sensor film, or a cover body, such as a polarizer and a touch panel, is bonded.

### Advantageous Effects

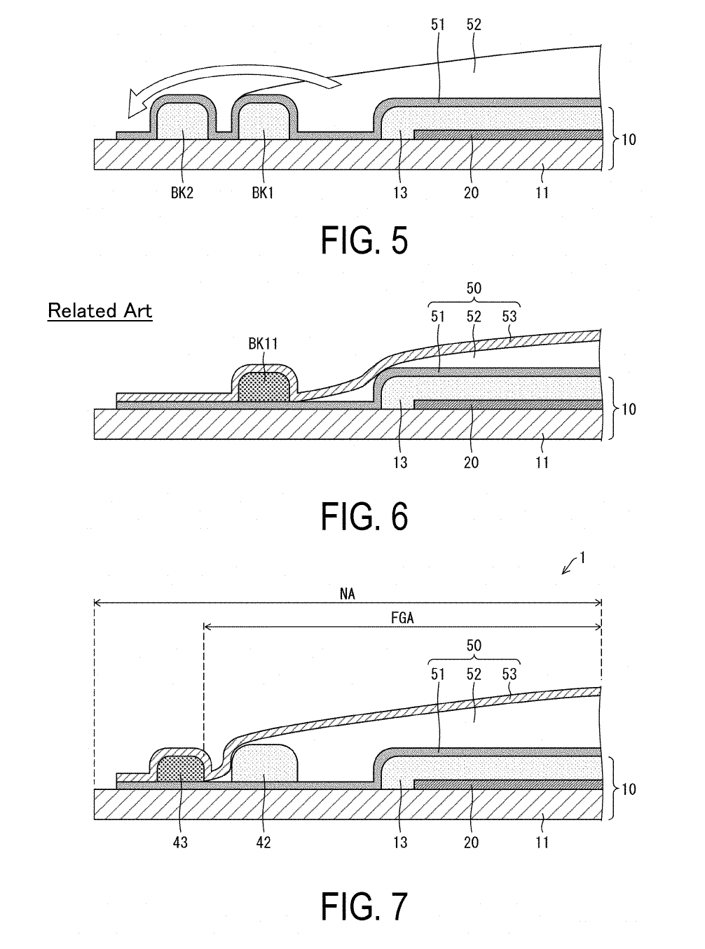

FIG. 5 is a cross-sectional view illustrating a structure of a damming portion in a known electro-optical device.

As illustrated in FIG. 5, in the known electro-optical device, a first bank BK1 and a second bank BK2 as damming portions are provided under a first inorganic layer 51.

The first inorganic layer 51 easily wet-spreads to improve application properties of an ink material. Thus, when the first inorganic layer 51 is layered on the first bank BK1 and the second bank BK2, a function of holding back the ink material of the first bank BK1 and the second bank BK2 does not sufficiently work, and the ink material may climb over not only the first bank BK1 being an inner protruding portion but also the second bank BK2 being an outer protruding portion as indicated by an arrow in FIG. 5.

When the ink material climbs over the second bank BK2, an organic layer 52 cannot be covered with a second inorganic layer 53, and an end portion of the organic layer 52 is exposed. Accordingly, moisture enters an electro-optical element layer through the organic layer 52, which damages an electro-optical element, and reliability of an electro-optical device thus decreases.

FIG. 6 is a cross-sectional view illustrating a structure of a damming portion when a liquid-repellent bank BK11 is provided on a first inorganic layer 51, as a comparative example.

When the liquid-repellent bank BK 11 is provided as a damming portion on a first inorganic layer 51 as illustrated in FIG. 6, an ink material can be sufficiently held back by only the bank BK11, and a bank does not need to be further formed outside the bank BK11.

However, the bank BK11 has liquid-repellent properties, and thus the ink material does not climb to a surface of the bank BK11 as in a case of a liquid-philic bank. Thus, when the bank BK11 is formed so as to be adjacent to a flattened layer 13 as illustrated in FIG. 6, the ink material constituting an organic layer 52 has a thickness gradually increasing from an end portion of the bank BK11 toward the flattened layer 13. However, the ink material cannot obtain a sufficient thickness even when the ink material reaches the flattened layer 13. Thus, with a foreign matter on the flattened layer 13, the foreign matter cannot be covered with the organic layer 52, and a second inorganic layer 53 may be ruptured. Accordingly, moisture enters an electro-optical element layer from a portion in which the foreign matter is exposed through the flattened layer 13, and reliability of an electro-optical device thus decreases.

On the other hand, the electro-optical device 1 according to the present embodiment can make up for faults of the electro-optical devices illustrated in FIG. 5 and FIG. 6.

According to the present embodiment, a damming portion surrounding the active region DA has a double structure of the liquid-philic protruding portion and the liquid-repellent protruding portion. In other words, the damming portion includes the liquid-philic protruding portion and the liquid-repellent protruding portion formed in this order from the inside (active region DA side). Accordingly, the following advantageous effects can be obtained.

According to the present embodiment, the liquid-repellent protruding portion can improve properties of holding back an ink material, reduce such a failure that an ink material overflows to the outside of the damming portion, and improve yields.

On the other hand, according to the present embodiment, the liquid-philic protruding portion can increase a height of a rise position of the organic layer 52. According to the present embodiment, the first liquid-philic protruding portion 42 is located inside the second liquid-repellent protruding portion 43, and thus the ink material climbs to the surface of the first protruding portion 42. Therefore, as illustrated in FIG. 1 and FIG. 3, a rise of the end portion of the organic layer 52 starts from an upper face end portion (upper portion) of the first protruding portion 42, and a film thickness of the organic layer 52 on the flattened layer 13 can be increased by a thickness of the first protruding portion 42.

Thus, according to the present embodiment, a film thickness of the organic layer 52 on the flattened layer 13 can be sufficiently secured. Therefore, according to the present embodiment, a foreign matter can be covered with the organic layer 52 even with the foreign matter on the flattened layer 13, and thus infiltration of moisture into the electro-optical element layer can be suppressed without the second inorganic layer 53 being ruptured by the foreign matter.

Since a rise position of the organic layer 52 can be increased as described above, a width of the film thickness gradual decrease region FGA (gradual decrease portion of a film thickness of the organic layer 52) illustrated in FIG. 1 and FIG. 3 do not increase. Thus, frame narrowing can be achieved.

### First Modified Example

Note that, as described above, in the present embodiment, the organic EL display device including the OLED element 34 as the electro-optical element is described as one example of the electro-optical device 1 according to the present embodiment. However, the electro-optical device 1 according to the present embodiment is not particularly limited as long as it is the flexible and bendable electro-optical device provided with the electro-optical element. Examples of the electro-optical element include an electro-optical element in which luminance and transmittance are controlled by an electric current, and an electro-optical element in which luminance and transmittance are controlled by voltage.

Examples of the electro-optical device provided with the electro-optical element controlled by the electric current include an Electro Luminescence (EL) display provided with Organic Light Emitting Diode (OLED) elements, an EL display such as an inorganic EL display provided with inorganic light emitting diode elements (inorganic EL elements), or a QLED display provided with Quantum-dot Light Emitting Diode (QLED) elements. Furthermore, the electro-optical element controlled by voltage can be, for example, a liquid crystal display element or the like.

The electro-optical device 1 according to the present embodiment is not limited to an image display device, and can be suitably used for an illumination device, an Integrated Circuits (IC) tag, an IC card, electronic paper, various flexible devices, and the like. The electro-optical device 1 may include only one electro-optical element depending on its use. In other words, the electro-optical device 1 may include at least one electro-optical element.

### Second Modified Example

In the present embodiment, the case where the first bank 41 is formed simultaneously with the flattened layer 13 in the circuit substrate formation step is described as an example. However, the present embodiment is not limited to this, and the first bank 41 may be formed simultaneously with the edge cover 35 by using the same material for the edge cover 35 in the electro-optical element formation step.

### Third Modified Example

In the present embodiment, the case where the first protruding portion 42 is the liquid-philic protruding portion and the second protruding portion 43 is the liquid-repellent protruding portion in the electro-optical device 1 according to the present embodiment is described as an example. However, the present embodiment is not limited thereto.

In the manufacturing method of the electro-optical device 1 according to the present embodiment, surface processing may be performed on the surface of the second protruding portion 43 by atmospheric pressure plasma, hydrogen plasma, or oxygen plasma before the second inorganic layer film formation step and after the organic layer formation step to increase adhesion between the second protruding portion 43 and the second inorganic layer 53.

The surface of the second protruding portion 43 has liquid-philic properties to the ink material by the surface processing, but a position of an edge of the organic layer 52 does not change by the surface processing because the ink material has already been cured and the organic layer 52 has been formed.

In other words, as long as the first protruding portion 42 has liquid-philic properties to the ink material and the second protruding portion 43 has liquid-repellent properties to the ink material in the organic layer formation step, the first protruding portion 42 and the second protruding portion 43 may both be liquid-philic protruding portions in the electro-optical device 1 formed at the end.

### Second Embodiment

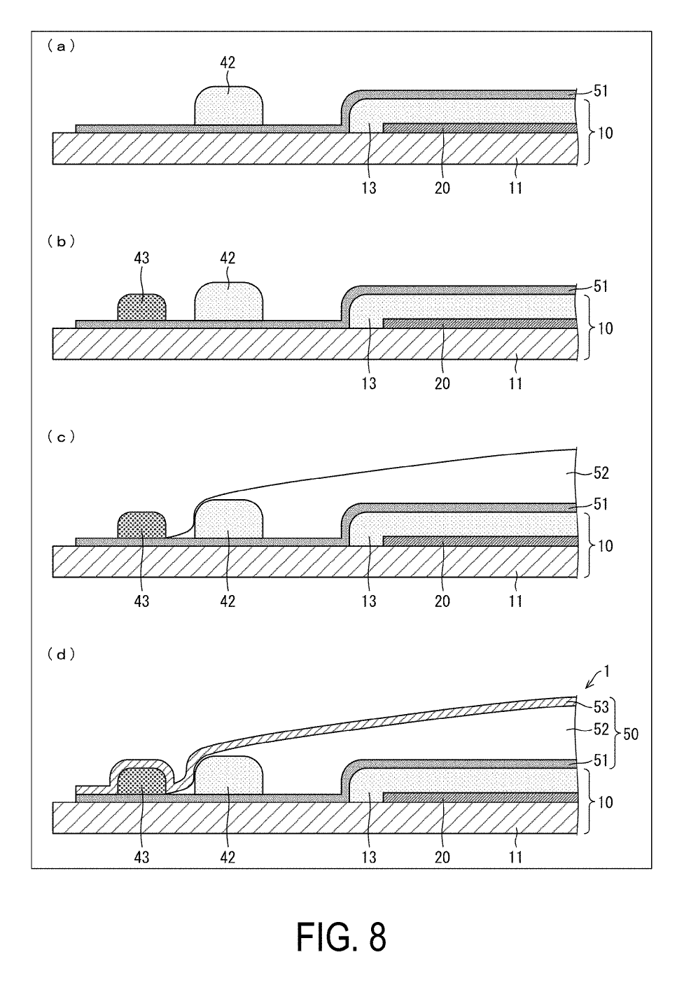

Another embodiment of the disclosure will be described as follows, mainly with reference to FIG. 7 and (a) to (d) of FIG. 8. The present embodiment will be described in terms of the differences between the present embodiment and the first embodiment, and components having the same function as the components described in the first embodiment are assigned the same reference signs, and a description thereof is omitted. Furthermore, the same modifications as those of the first embodiment can also be applied to the present embodiment.

### Schematic Configuration of Electro-Optical Device

FIG. 7 is a cross-sectional view schematically illustrating a schematic configuration of main portions of an electro-optical device 1 according to the present embodiment.

As illustrated in FIG. 7, the electro-optical device 1 according to the present embodiment is identical to the electro-optical device 1 according to the first embodiment except for that a first protruding portion 42 formed of a first bank in a frame shape and a second protruding portion 43 formed of a second bank in a frame shape are formed on a first inorganic layer 51.

At least a surface of the first bank has liquid-philic properties. The first bank has liquid-philic properties to an ink material itself, or a surface of the first bank is subjected to liquid-philic processing.

### Manufacturing Method of Electro-Optical Device 1

Next, with reference to FIG. 7 and (a) to (d) of FIG. 8, a manufacturing method of the electro-optical device 1 will be described below. (a) to (d) of FIG. 8 are cross-sectional views illustrating the manufacturing method of the electro-optical device 1 in order of steps.

The manufacturing method of the electro-optical device 1 according to the present embodiment is identical to that in the first embodiment except for that the first protruding portion 42 that has at least a surface having liquid-philic properties and is formed of the first bank is formed after a first inorganic layer formation step.

Thus, in the present embodiment, steps to the first inorganic layer formation step are first performed similarly to the first embodiment except for that the first bank is not formed.

In other words, in the present embodiment, as illustrated in FIG. 7 and (a) of FIG. 8, a circuit substrate 10 is formed by a publicly known method (circuit substrate formation step). Next, an electro-optical element layer including an electro-optical element is formed on the circuit substrate 10 by a publicly known method according to a kind of the electro-optical element (electro-optical element formation step). Subsequently, the first inorganic layer 51 that covers the electro-optical element is film-formed by using a mask (not illustrated) opened in a region including an active region DA (more specifically, a region surrounding a region in which the second protruding portion 43 is to be formed similarly to the first embodiment) (first inorganic layer formation step).

Next, the first protruding portion 42 formed of the first bank in a frame shape is formed as a liquid-philic protruding portion on the first inorganic layer 51 so as to surround a flattened layer 13 (liquid-philic protruding portion formation step).

The first protruding portion 42 can be formed by, for example, applying a material (application liquid) for the first protruding portion 42 in a frame shape formed of a continuous line to the outside of the flattened layer 13 by an ink-jet method or a printing method, and curing the material with irradiation of UV (ultraviolet) light and the like.

At this time, by using an application liquid having liquid-philic properties to the ink material as the application liquid, the first protruding portion 42 (first bank) having liquid-philic properties itself can be formed.

Instead of forming the first protruding portion 42 having liquid-philic properties itself (namely, in the entire first protruding portion 42), processing (liquid-philic processing) to increase wettability with respect to the ink material, such as atmospheric pressure plasma processing, may be performed on the surface of the first protruding portion 42 before formation of the second protruding portion 43 and after formation of the first protruding portion 42 (first bank).

Note that, when the liquid-philic processing such as atmospheric pressure plasma processing is performed on the surface of the first protruding portion 42 before formation of the second protruding portion 43, a material having liquid-philic properties to the ink material may not always need to be used as a material for the first protruding portion 42.

Subsequently, as illustrated in FIG. 7 and (b) to (d) of FIG. 8, a liquid-repellent protruding portion formation step, an organic layer formation step, and a second inorganic layer formation step are performed similarly to the first embodiment, and then the second protruding portion 43, an organic layer 52, and a second inorganic layer 53 are formed in order.

### Advantageous Effects

As described above, the present embodiment can also obtain similar advantageous effects to those of the first embodiment by providing a double structure of the liquid-philic protruding portion and the liquid-repellent protruding portion to a damming portion.

### Third Embodiment

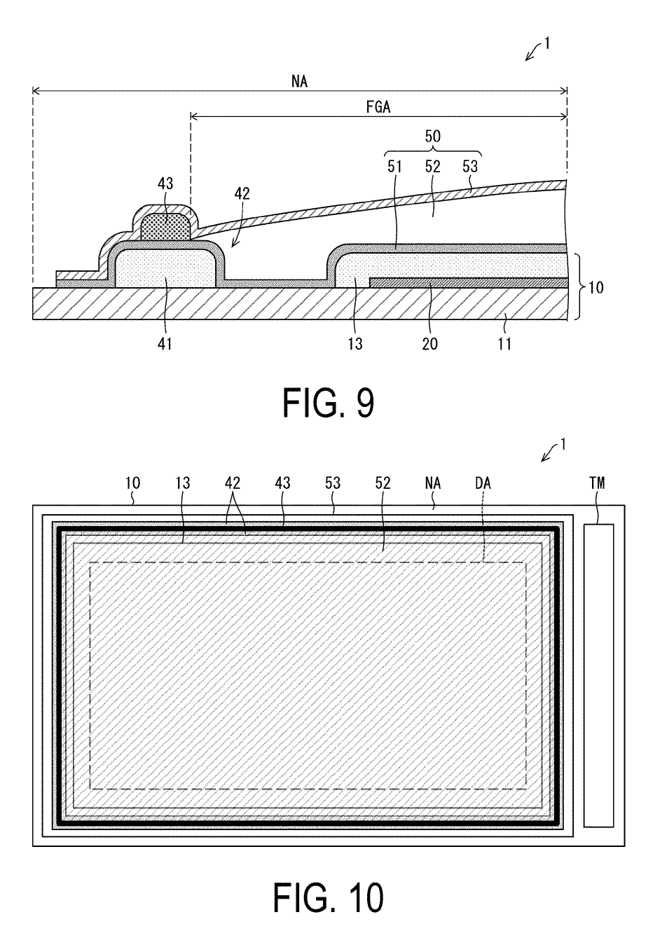

Still another embodiment of the disclosure will be described as follows, mainly with reference to FIG. 9 and (a) to (d) of FIG. 11. The present embodiment will be described in terms of the differences between the present embodiment and the first and second embodiments, and components having the same function as the components described in the first and second embodiments are assigned the same reference signs, and a description thereof is omitted. Furthermore, the same modifications as those of the first and second embodiments can also be applied to the present embodiment.

### Schematic Configuration of Electro-Optical Device

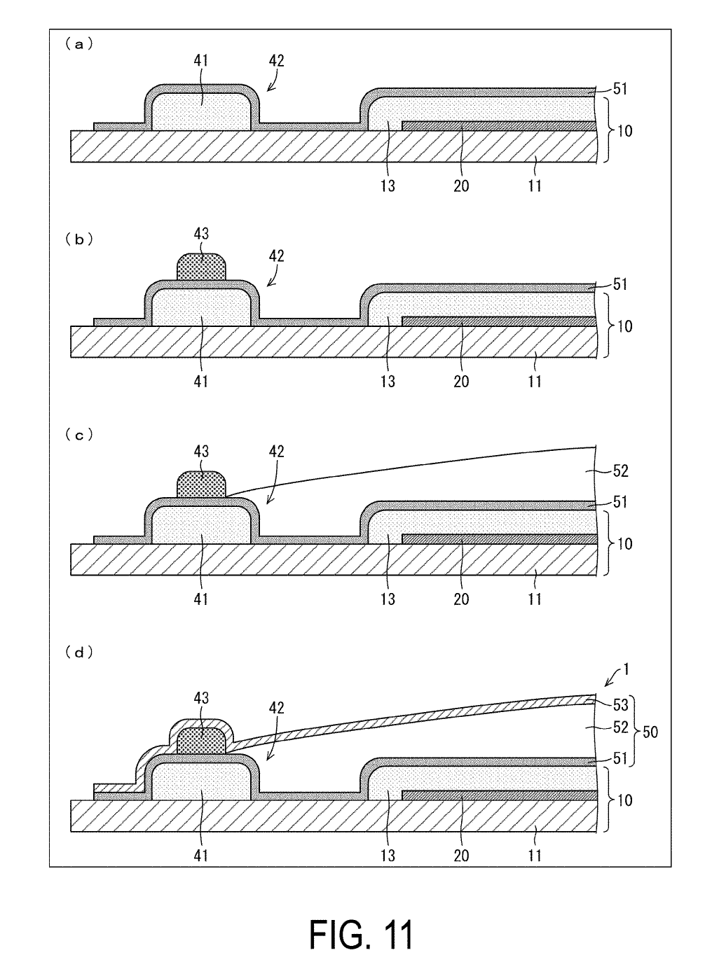

FIG. 9 is a cross-sectional view schematically illustrating a schematic configuration of main portions of an electro-optical device 1 according to the present embodiment. FIG. 10 is a plan view schematically illustrating a schematic configuration of the main portions of the electro-optical device 1 according to the present embodiment.

As illustrated in FIG. 9 and FIG. 10, the electro-optical device 1 according to the present embodiment is identical to the electro-optical device 1 according to the first embodiment except for that a second protruding portion 43 is layered on a first protruding portion 42.

Note that, a first bank 41 is covered with a first inorganic layer 51 in the example illustrated in FIG. 9. The second protruding portion 43 formed of a second bank is formed on the first protruding portion 42 formed of the first bank 41 covered with the first inorganic layer 51.

The first inorganic layer 51 provided between the first bank 41 and the second protruding portion 43 has liquid-philic properties to an ink material used for an organic layer 52. Thus, a top of the first protruding portion 42 has liquid-philic properties to the ink material except for a portion on which the second protruding portion 43 having liquid-repellent properties to the ink material is located.

### Manufacturing Method of Electro-Optical Device 1

Next, with reference to FIG. 9 and (a) to (d) of FIG. 11, a manufacturing method of the electro-optical device 1 will be described below. (a) to (d) of FIG. 11 are cross-sectional views illustrating the manufacturing method of the electro-optical device 1 in order of steps.

The manufacturing method of the electro-optical device 1 according to the present embodiment is identical to that in the first embodiment except for that the second protruding portion 43 is formed on the first protruding portion 42 in a liquid-repellent protruding portion formation step.

Thus, in the present embodiment, as illustrated in FIG. 9 and (a) of FIG. 11, a step to a first inorganic layer formation step is first performed similarly to the first embodiment. However, a width of an upper face of the first bank 41 preferably falls within a range of 14 μm to 94 μm, for example, because the second protruding portion 43 is formed on the first protruding portion 42.

Next, as illustrated in FIG. 9 and (b) of FIG. 11, a liquid-repellent protruding portion formed of a second bank in a frame shape is formed as the second protruding portion 43 on the first protruding portion 42 (in other words, on the first bank 41 with the first inorganic layer 51 interposed therebetween) (liquid-repellent protruding portion formation step).

The second protruding portion 43 can be formed by, for example, applying an application liquid having liquid-repellent properties to the ink material used for the organic layer 52 in a frame shape formed of a continuous line by an ink-jet method or a printing method, and curing the application liquid with irradiation of UV (ultraviolet) light and the like, similarly to the first embodiment.

A width of an upper face of the first protruding portion 42 exposed from the second protruding portion 43 within a region surrounded by the second protruding portion 43 (namely, the inside of the second protruding portion 43) in a plan view preferably falls within a range of 2 μm to 78 μm. When a width of the upper face of the first protruding portion 42 exposed from the second protruding portion 43 is less than 2 μm, a portion that is not flat is generated in the upper face of the first protruding portion 42 due to processing accuracy of the first protruding portion 42, the organic layer 52 has a small thickness at an end portion of a flattened layer 13, and foreign matter may be insufficiently covered. In other words, when the upper face of the first protruding portion 42 is flat, the organic layer 52 has a thickness gradually increasing from the first protruding portion 42 toward the active region DA at a contact angle θ (in this case, θ<5 degrees) of the ink material to be the organic layer 52 with respect to the first protruding portion 42. However, when the upper face of the first protruding portion 42 does not have a flat region and has an inclination of −β degrees, the organic layer 52 has such a shape that has a thickness increasing from the first protruding portion 42 toward the active region DA according to an angle of α-β degrees near the first protruding portion 42. Therefore, the organic layer 52 has a small thickness at the end portion of the flattened layer 13. When a width of the upper face of the first protruding portion 42 exposed from the second protruding portion 43 exceeds 78 μm, a width of the second protruding portion 43 formed on the first protruding portion 42 becomes too small. Alternatively, a width of the upper face of the first protruding portion 42 needs to be increased in order to secure a width of the second protruding portion 43 formed on the first protruding portion 42, and a width of the non-active region NA is increased accordingly.

Thus, a width of the second protruding portion 43 in the plan view preferably falls within a range of 10 μm to 90 μm. As described above, when the second protruding portion 43 has a width of less than 10 μm, formation of a shape of the second protruding portion 43 is insufficient due to small foreign matter and the like, and the second protruding portion 43 may not completely surround the active region DA and may be interrupted. Furthermore, when the second protruding portion 43 has a width of less than 10 μm, a contact area between the second protruding portion 43 and the first inorganic layer 51 is small, and film peeling of the second protruding portion 43 may occur. On the other hand, when the second protruding portion 43 has a width exceeding 90 μm, a width of the upper face of the first protruding portion 42 exposed from the second protruding portion 43 becomes too small. Alternatively, a width of the upper face of the first protruding portion 42 needs to be increased in order to secure a width of the upper face of the first protruding portion 42 exposed from the second protruding portion 43, and a width of the non-active region NA is increased accordingly.

Note that, as described above, as long as the second protruding portion 43 is formed such that a width of the upper face of the first protruding portion 42 exposed from the second protruding portion 43 inside the second protruding portion 43 is at least 2 μm, a width of the upper face of the first protruding portion 42 exposed from the second protruding portion 43 may be different inside and outside the second protruding portion 43.

In other words, the second protruding portion 43 may be formed on the first protruding portion 42, for example, toward the outside, and, for example, an outer peripheral surface of the second protruding portion 43 may be substantially flush with an outer peripheral surface of the first protruding portion 42, and the first protruding portion 42 may be formed in a step shape in which the upper face of the first protruding portion 42 is exposed only inside the second protruding portion 43.

Note that, even when the second protruding portion 43 is formed on the first protruding portion 42 in such a manner, a height of the first protruding portion 42 and a height of the second protruding portion 43 are formed to be similar to those in the first and second embodiments for the same reason as that of the first and second embodiments.

Subsequently, as illustrated in FIG. 9, (c) and (d) of FIG. 11, an organic layer formation step and a second inorganic layer formation step are performed similarly to the first embodiment, and then the organic layer 52 and a second inorganic layer 53 are formed.

### Advantageous Effects

According to the present embodiment, the advantageous effects similar to those of the first and second embodiments can be obtained because the damming portion surrounding the active region DA includes the liquid-philic protruding portion exposed from the liquid-repellent protruding portion and the liquid-repellent protruding portion formed in the order from the inside (active region DA side).

According to the present embodiment, as described above, the surface of the first protruding portion 42 has liquid-philic properties to the ink material used for the organic layer 52 except for a portion on which the second protruding portion 43 having liquid-repellent properties to the ink material is located.

Thus, the ink material climbs to the surface of the first protruding portion 42 having liquid-philic properties, but is held back by the second protruding portion 43. A rise position of an end portion of the organic layer 52 in the electro-optical device 1 according to the present embodiment is an end portion of the second protruding portion 43 on the upper face of the first protruding portion 42. Thus, according to the present embodiment, a film thickness of the organic layer 52 on the flattened layer 13 can be increased further than that in the case where a rise of the end portion of the organic layer 52 starts from the upper face end portion of the first protruding portion 42 as in the first and second embodiments.

### Modified Example

Note that, as illustrated in FIG. 9, the case where the first bank 41 is covered with the first inorganic layer 51 is described as an example in the present embodiment. However, the present embodiment is not limited to this, and the present embodiment may have a configuration in which the first protruding portion 42 that has at least a surface having liquid-philic properties and is formed of the first bank is formed on the first inorganic layer 51 as described in the second embodiment.

### Fourth Embodiment

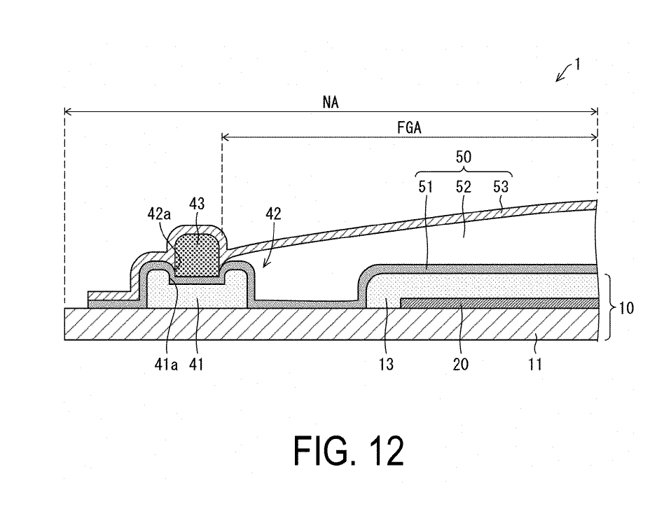

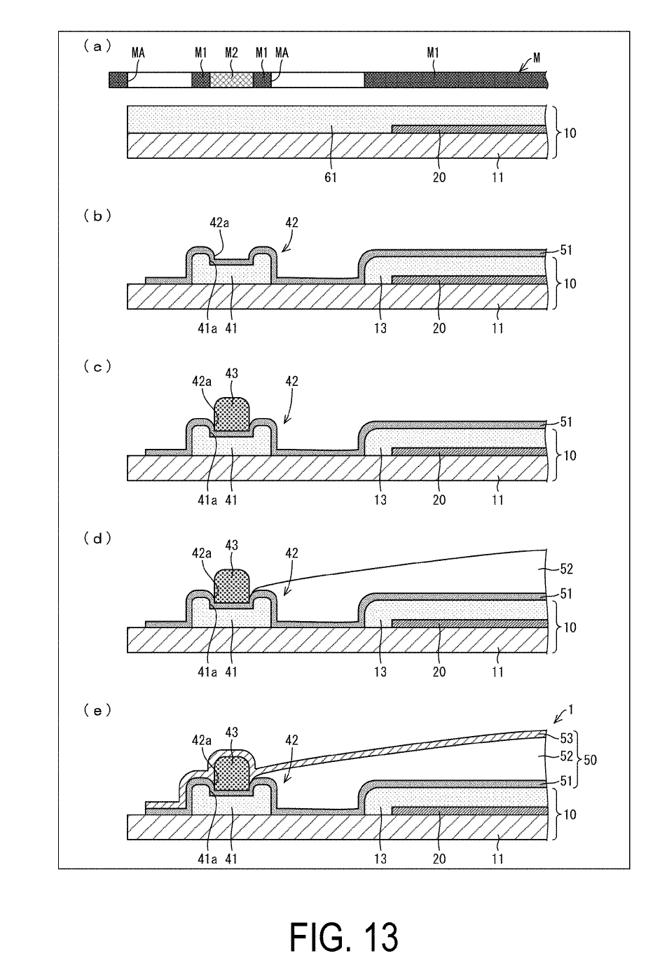

Still another embodiment of the disclosure will be described as follows, mainly with reference to FIG. 12 and (a) to (e) of FIG. 13. The present embodiment will be described in terms of the differences between the present embodiment and the first to third embodiments, and components having the same function as the components described in the first to third embodiments are assigned the same reference signs, and a description thereof is omitted. Furthermore, the same modifications as those of the first to third embodiments can also be applied to the present embodiment.

### Schematic Configuration of Electro-Optical Device

FIG. 12 is a cross-sectional view schematically illustrating a schematic configuration of main portions of an electro-optical device 1 according to the present embodiment.

As illustrated in FIG. 12, in the electro-optical device 1 according to the present embodiment, a first bank 41 includes a recessed portion 41a having a frame shape along a shape of the first bank 41 in an upper face thereof. Thus, in the electro-optical device 1 according to the present embodiment, a first protruding portion 42 includes a recessed portion 42a having a frame shape along a shape of the first protruding portion 42 in an upper face thereof. A second protruding portion 43 is formed in the recessed portion 42a. The electro-optical device 1 according to the present embodiment is the same as the electro-optical device 1 according to the third embodiment except for this point.

However, also in the present embodiment, the first protruding portion 42 that has at least a surface having liquid-philic properties and is formed of the first bank may be formed on a first inorganic layer 51 as described in the second and third embodiments, and the recessed portion 42a may be formed in the first protruding portion 42 formed of the first bank.

### Manufacturing Method of Electro-Optical Device 1

With reference to FIG. 12 and (a) to (e) of FIG. 13, a manufacturing method of the electro-optical device 1 will be described below. (a) to (e) of FIG. 13 are cross-sectional views illustrating the manufacturing method of the electro-optical device 1 in order of steps.

As one example, as illustrated in FIG. 12, a case where the first protruding portion 42 is formed of the first bank 41 covered with the first inorganic layer 51 is described below as an example. As one example, a case where the first bank 41 is formed on the same plane as a flattened layer 13 simultaneously with the flattened layer 13 in a circuit substrate formation step by using the same material as that for the flattened layer 13 as a material for the first bank 41 is also described below as an example.

First, as illustrated in FIG. 12 and (a) of FIG. 13, a circuit substrate 10 in which the flattened layer 13 covering a circuit portion 20 is formed is prepared on a base 11, and, at the same time, the first bank 41 having a frame shape and surrounding the flattened layer 13 is formed on the circuit substrate 10 similarly to the third embodiment except for that a halftone mask is used in a formation step of the flattened layer 13 (circuit substrate/first bank formation step).

(a) of FIG. 13 illustrates that, for example, a positive-working photosensitive resin 61 is used as a material for the flattened layer 13 and the first bank 41 as an example.

In the present embodiment, as illustrated in (a) of FIG. 13, a driving element layer (for example, the TFT layer 12 illustrated in FIG. 3) including the circuit portion 20 is formed, and then the photosensitive resin 61 is applied to the driving element layer by a publicly known method similarly to the third embodiment.

Next, the flattened layer 13 and the first bank 41 formed of the photosensitive resin 61 are patterned and formed by photolithography and the like.

In the present embodiment, a mask M including an opening MA, a light blocking portion M1, and a halftone portion M2 is used for the pattern. The opening MA is provided so as to face a region of the photosensitive resin 61 on the base 11 except for formation regions of the flattened layer 13 and the first bank 41. The light blocking portion M1 covers the formation region of the flattened layer 13 and a formation region of a portion of the first bank 41 except for the recessed portion 41a in the photosensitive resin 61. The halftone portion M2 covers a formation region of the recessed portion 41a of the first bank 41 in the photosensitive resin 61.

When the photosensitive resin 61 is irradiated with light such as UV light via the mask M, the photosensitive resin 61 is irradiated with light passing through the opening MA and the halftone portion M2. In this way, a region of the photosensitive resin 61 except for the flattened layer 13 and the first bank 41 is exposed, and the formation region of the recessed portion 41a of the first bank 41 is also half-exposed. Subsequently, the flattened layer 13 and the first bank 41 having a frame shape and having the upper face with the recessed portion 41a having a frame shape in a plan view, which are formed of the photosensitive resin 61, are simultaneously patterned and formed by performing development.

Note that, the flattened layer 13 and the first bank 41 including the recessed portion 41a may, of course, be individually formed by photolithography, double exposure, and the like, or the flattened layer 13 and the first bank 41 including the recessed portion 41a may be formed in different steps by using different masks.

In the present embodiment, a width of an upper face of the first bank 41 including the recessed portion 41a preferably falls within a range of 16 μm to 106 μm, for example, because the second protruding portion 43 is formed on the first protruding portion 42 similarly to the third embodiment.

A width of the recessed portion 41a in the first bank 41 is formed such that a width of the second protruding portion 43 in the plan view suitably falls within a range of 10 μm to 90 μm as described in the third embodiment. Specifically, a width of the recessed portion 41a of the first bank 41 is formed so as to fall within a range of 30 μm to 70 μm, for example.

A height of a portion of the first bank 41 except for a portion thereof in the recessed portion 41a (in other words, a height of a portion of the first bank 41 exposed from the second protruding portion 43 in the first protruding portion 42) is formed at a height similar to a height of the first bank 41 in the first to third embodiments for the same reason of the first to third embodiments.

A depth of the recessed portion 41a in the first bank 41 is suitably greater than or equal to 3 μm. Note that, an upper limit of a depth of the recessed portion 41a is not particularly limited (but the recessed portion 41a is a recessed portion, and thus the upper limit is less than a height of the first bank 41). When the recessed portion 41a has a depth of less than 0.5 μm, an ink material used for the second protruding portion 43 described later may overflow from the recessed portion 41a.

Next, as illustrated in FIG. 12 and (b) of FIG. 13, an electro-optical element formation step and a first inorganic layer formation step are performed similarly to the third embodiment, and an electro-optical element layer (for example, an OLED element layer 30) and the first inorganic layer 51 are formed in order. In this way, the first protruding portion 42 formed of the first bank 41 covered with the first inorganic layer 51 is formed as a liquid-philic protruding portion (liquid-philic protruding portion formation step).

Note that, a height of a portion of the first protruding portion 42 except for a portion thereof in the recessed portion 42a (in other words, a height of a portion of the first bank 41 exposed from the second protruding portion 43 in the first protruding portion 42) is formed at a height similar to a height of the first protruding portion 42 in the first to third embodiments for the same reason of the first to third embodiments.

In the present embodiment, the recessed portion 42a formed of the recessed portion 41a covered with the first inorganic layer 51 is formed in the upper face of the first protruding portion 42 by forming the recessed portion 41a in the first bank 41.

Next, as illustrated in FIG. 12 and (c) of FIG. 13, an application liquid having liquid-repellent properties to an ink material used for an organic layer 52 (hereinafter referred to as an “ink material (I)” for the sake of description) is applied to the inside of the recessed portion 42a by an ink-jet method. The recessed portion 42a functions as a liquid pool that stores the application liquid (namely, an ink material used for the second protruding portion 43: hereinafter referred to as an “ink material (II)” for the sake of description).

Next, the application liquid is cured by irradiating the application liquid with UV (ultraviolet) light and the like. In this way, a liquid-repellent protruding portion formed of the second bank in a frame shape is formed as the second protruding portion 43 on the first protruding portion 42 (liquid-repellent protruding portion formation step).

At this time, the second protruding portion 43 is preferably formed such that a height of the second protruding portion 43 protruding from the upper face of the first protruding portion 42 that is not covered with the second protruding portion 43 (namely, a height of the second protruding portion 43 above the upper face of the first protruding portion 42 that is not covered with the second protruding portion 43) falls within a range of 0.5 μm to 5 μm. When the second protruding portion 43 protruding from the upper face of the first protruding portion 42 has a height of less than 0.5 μm, the ink material used for the organic layer 52 may climb over the second protruding portion 43 and overflow. When the second protruding portion 43 protruding from the upper face of the first protruding portion 42 has a height exceeding 5 μm, residual stress of a second inorganic layer 53 may concentrate at the bent portion formed by the second protruding portion 43 and the base 11, and film peeling of the second inorganic layer 53 may occur.

Subsequently, as illustrated in FIG. 12, (d) and (e) of FIG. 13, an organic layer formation step and a second inorganic layer formation step are performed similarly to the third embodiment, and then the organic layer 52 and the second inorganic layer 53 are formed in order.

### Advantageous Effects

Also in the present embodiment, the advantageous effects similar to those of the third embodiment can be obtained because the damming portion surrounding the active region DA includes the liquid-philic protruding portion exposed from the liquid-repellent protruding portion and the liquid-repellent protruding portion formed in the order from the inside (active region DA side).

Further, according to the present embodiment, by applying the ink material (II) used for the second protruding portion 43 (namely, an application liquid having liquid-repellent properties to the ink material used for the organic layer 52) to the inside of the recessed portion 42a provided in the upper face of the first protruding portion 42, the ink material (II) does not wet-spread to the outside of the recessed portion 42a even when viscosity of the ink material (II) is reduced to a certain degree. Thus, according to the present embodiment, the ink material (II) can be easily adjusted within a range of desired viscosity suitable for an ink-jet method, and the second protruding portion 43 can be easily and stably formed by the ink-jet method.

### Fifth Embodiment

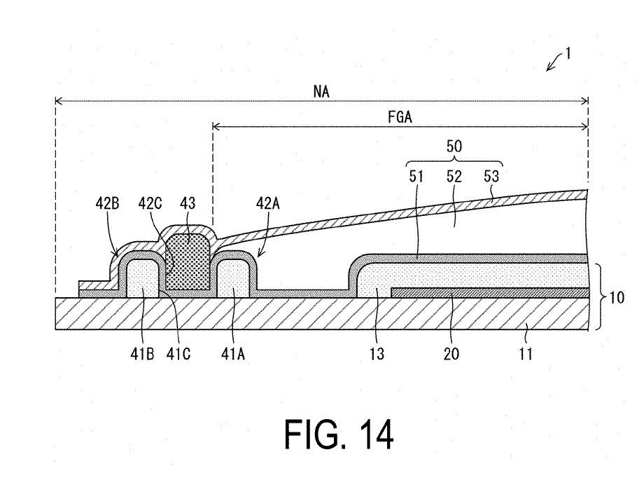

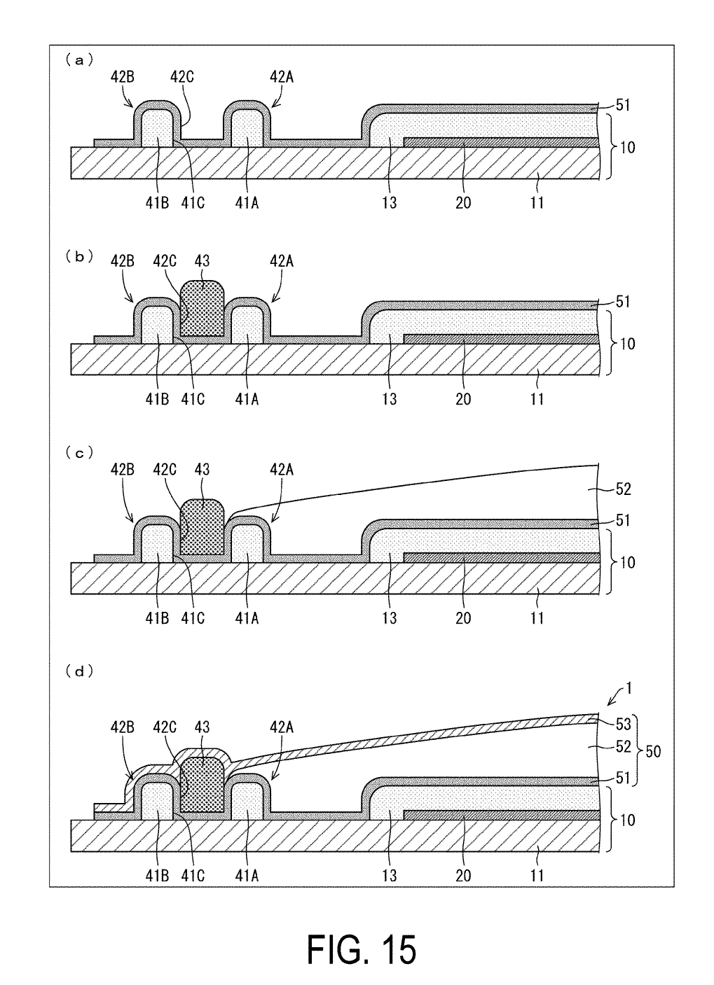

Still another embodiment of the disclosure will be described as follows, mainly with reference to FIG. 14 and (a) to (d) of FIG. 15. The present embodiment will be described in terms of the differences between the present embodiment and the first to fourth embodiments, and components having the same function as the components described in the first to fourth embodiments are assigned the same reference signs, and a description thereof is omitted. Furthermore, the same modifications as those of the first to fourth embodiments can also be applied to the present embodiment.

### Schematic Configuration of Electro-Optical Device

FIG. 14 is a cross-sectional view schematically illustrating a schematic configuration of main portions of an electro-optical device 1 according to the present embodiment.

As illustrated in FIG. 14, in the electro-optical device 1 according to the present embodiment, a first bank 41 is divided (separated) into a first bank 41A and a first bank 41B by a slit 41C instead of including a recessed portion 41a. Thus, in the present embodiment, a first protruding portion 42 includes a first protruding portion 42A formed of the first bank 41A covered with a first inorganic layer 51 and a first protruding portion 42B formed of the first bank 41B covered with the first inorganic layer 51. A recessed portion 42C that is formed of the slit 41C covered with the first inorganic layer 51 and has a frame shape is formed between the first protruding portion 42A and the first protruding portion 42B. A second protruding portion 43 is formed in the recessed portion 42C. The electro-optical device 1 according to the present embodiment is the same as the electro-optical device 1 according to the fourth embodiment except for this point.

However, also in the present embodiment, the first protruding portions 42A and 42B may be respectively formed of the first banks 41A and 41B each having at least a surface having liquid-philic properties by forming the first banks 41A and 41B each having at least a surface having liquid-philic properties as the first bank 41 on the first inorganic layer 51.

Thus, in the electro-optical device 1 according to the present embodiment, a slit formed of the slit 41C instead of the recessed portion 42C may be provided between the first protruding portion 42A and the first protruding portion 42B respectively formed of the first banks 41A and 41B that are formed on the first inorganic layer 51 and each have at least a surface having liquid-philic properties. Then, the electro-optical device 1 may have a configuration in which the second protruding portion 43 is provided in the slit 41C between the first protruding portions 42A and 42B respectively formed of the first banks 41A and 41B.

### Manufacturing Method of Electro-Optical Device 1

With reference to FIG. 14 and (a) to (d) of FIG. 15, a manufacturing method of the electro-optical device 1 will be described below. (a) to (d) of FIG. 15 are cross-sectional views illustrating the manufacturing method of the electro-optical device 1 in order of steps.

As one example, as illustrated in FIG. 14, a case where the first protruding portion 42 is formed of the first banks 41A and 41B that are covered with the first inorganic layer 51, are separated into two, and have a double-frame shape is described below as an example. As one example, a case where the first bank 41 is formed on the same plane as a flattened layer 13 simultaneously with the flattened layer 13 in a circuit substrate formation step by using the same material as that for the flattened layer 13 as a material for the first bank 41 is also described below as an example.

First, as illustrated in FIG. 14 and (a) of FIG. 15, a circuit substrate 10 in which the flattened layer 13 covering a circuit portion 20 is formed on a base 11, and, at the same time, the first banks 41A and 41B having a frame shape and surrounding the flattened layer 13 are formed on the circuit substrate 10 similarly to the fourth embodiment except for that the first bank 41 that is formed of the first banks 41A and 41B being separated into two and having the slit 41C therebetween and has a double-frame shape is patterned and formed in a formation step of the flattened layer 13 (circuit substrate/first bank formation step).

The first banks 41A and 41B can be formed by, for example, patterning the photosensitive resin 61 by using the mask M provided with the opening MA instead of the halftone portion M2 in (a) of FIG. 13.

Note that, a distance between an inner peripheral surface of the first bank 41A on the flattened layer 13 side and an outer peripheral surface of the first bank 41B located outside the first bank 41A (in other words, a width of the upper face of the first bank 41 including the slit 41C) is set similarly to a width of the upper face of the first bank 41 including the recessed portion 41a in the fourth embodiment.

Further, a width of the slit 41C is set similarly to a width of the recessed portion 41a in the fourth embodiment. Similarly, a height of the first banks 41A and 41B is formed at a height similar to a height of the first bank 41 in the fourth embodiment.

Next, an electro-optical element formation step and a first inorganic layer formation step are performed similarly to the fourth embodiment, and an electro-optical element layer (for example, an OLED element layer 30) and the first inorganic layer 51 are formed in order. In this way, the two first protruding portions 42A and 42B respectively formed of the first banks 41A and 41B that have the recessed portion 42C formed of the slit 41C covered with the first inorganic layer 51 being provided therebetween are formed as liquid-philic protruding portions (liquid-philic protruding portion formation step).

Note that, a height of the first protruding portions 42A and 42B is formed at a height similar to a height of a portion of the first protruding portion 42 exposed from the second protruding portion 43 (in other words, a height of the first protruding portion 42 in the first to third embodiments) in the fourth embodiment for the same reason of the fourth embodiment.

Next, as illustrated in FIG. 14 and (b) of FIG. 15, an application liquid having liquid-repellent properties to an ink material used for an organic layer 52 (namely, the “ink material (I)”) is applied between the first protruding portion 42A and the first protruding portion 42B (to the inside of the recessed portion 42C in the example illustrated in FIG. 14 and (b) of FIG. 15) by an ink-jet method. The recessed portion 42C functions as a liquid pool that stores the application liquid (namely, the ink material (II)).

Next, the application liquid is cured by irradiating the application liquid with UV (ultraviolet) light and the like. In this way, a liquid-repellent protruding portion formed of a second bank having a frame shape is formed as the second protruding portion 43 between the first protruding portion 42A and the first protruding portion 42B (liquid-repellent protruding portion formation step).

Note that, a height of the second protruding portion 43 is formed such that a height of the second protruding portion 43 protruding from an upper face of the first protruding portions 42A and 42B (namely, a height of the second protruding portion 43 above the upper face of the first protruding portions 42A and 42B) is formed at a height similar to a height of the second protruding portion 43 protruding from the upper face of the first protruding portion 42 that is not covered with the second protruding portion 43 in the fourth embodiment for the same reason of the fourth embodiment.

Subsequently, as illustrated in FIG. 14, (c) and (d) of FIG. 15, an organic layer formation step and a second inorganic layer formation step are performed similarly to the fourth embodiment, and then the organic layer 52 and a second inorganic layer 53 are formed in order.

### Advantageous Effects

As described above, also in the present embodiment, the damming portion surrounding the active region DA includes the liquid-philic protruding portion exposed from the liquid-repellent protruding portion and the liquid-repellent protruding portion formed in the order from the inside (active region DA side). Further, in the present embodiment, the ink material (II) used for the second protruding portion 43 is applied to the inside of the recessed portion 42C. Accordingly, the present embodiment can also obtain similar advantageous effects to those of the fourth embodiment.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Electro-optical device
10 Circuit substrate (support body)
11 Base
12 TFT layer
13 Flattened layer
20 Circuit portion
30 OLED element layer
34 OLED element (electro-optical element)
41, 41A, 41B First bank
41a, 42a, 42C recessed portion
41C Slit
42, 42A, 42B First protruding portion (liquid-philic protruding portion)
43 Second protruding portion (liquid-repellent protruding portion)
50 Sealing film
51 First inorganic layer
52 Organic layer
53 Second inorganic layer
61 Photosensitive resin

1. A manufacturing method of an electro-optical device including at least one electro-optical element and a sealing film, the sealing film sealing the electro-optical element on a support body, the sealing film including an organic layer obtained by curing an ink material, a first inorganic layer, and a second inorganic layer, the first inorganic layer and the second inorganic layer sandwiching the organic layer, the manufacturing method comprising:
a liquid-philic protruding portion formation step for forming a liquid-philic protruding portion, the liquid-philic protruding portion having a surface having liquid-philic properties to the ink material, the liquid-philic protruding portion having a frame shape, the liquid-philic protruding portion surrounding the electro-optical element;
a liquid-repellent protruding portion formation step for forming a liquid-repellent protruding portion, the liquid-repellent protruding portion having a surface having liquid-repellent properties to the ink material, the liquid-repellent protruding portion having a frame shape, the liquid-repellent protruding portion surrounding the liquid-philic protruding portion, at least a part of the liquid-philic protruding portion being located inside the liquid-repellent protruding portion; and
an organic layer formation step for applying the ink material to a region surrounded by the liquid-philic protruding portion and then curing the ink material and forming the organic layer.

2. The manufacturing method of an electro-optical element according to claim 1,
wherein the liquid-philic protruding portion formation step includes
a frame-shaped bank formation step for forming a bank having a frame shape on the support body, the bank surrounding the electro-optical element, and
a first inorganic layer formation step for covering the bank with the first inorganic layer having a surface having liquid-philic properties to the ink material.

3. The manufacturing method of an electro-optical device according to claim 2,
wherein the liquid-repellent protruding portion is formed on the first inorganic layer in the liquid-repellent protruding portion formation step.

4. The manufacturing method of an electro-optical device according to claim 3, further comprising:
a second inorganic layer formation step for forming the second inorganic layer after the organic layer formation step,
wherein the second inorganic layer covers the organic layer, the liquid-philic protruding portion, and the liquid-repellent protruding portion in the second inorganic layer formation step.

5. The manufacturing method of an electro-optical device according to claim 3, further comprising:
a surface processing step for performing surface processing on a surface of the liquid-repellent protruding portion by atmospheric pressure plasma, hydrogen plasma, or oxygen plasma after the organic layer formation step; and
a second inorganic layer formation step for forming the second inorganic layer after the surface processing step,
wherein the second inorganic layer covers the organic layer, the liquid-philic protruding portion, and a protruding portion obtained by performing surface processing on the liquid-repellent protruding portion in the surface processing step in the second inorganic layer formation step.

6-9. (canceled)

10. The manufacturing method of an electro-optical device according to claim 1, further comprising:
a first inorganic layer formation step for forming the first inorganic layer having a surface having liquid-philic properties to the ink material on the support body,
wherein the liquid-philic protruding portion formed of a bank having at least a surface having liquid-philic properties to the ink material is formed on the first inorganic layer in the liquid-philic protruding portion formation step.

11. The manufacturing method of an electro-optical device according to claim 10,
wherein the liquid-repellent protruding portion is formed on the first inorganic layer in the liquid-repellent protruding portion formation step.

12. The manufacturing method of an electro-optical device according to claim 1,
wherein the liquid-repellent protruding portion surrounds the liquid-philic protruding portion at a distance from the liquid-philic protruding portion on the outside of the liquid-philic protruding portion, in the liquid-repellent protruding portion formation step.

13. The manufacturing method of an electro-optical device according to claim 1,
wherein the liquid-philic protruding portion is formed of frame-shaped liquid-philic protruding portions being separated into two and having a double-frame shape,
the frame-shaped liquid-philic protruding portions separated into two are formed as the liquid-philic protruding portion in the liquid-philic protruding portion formation step, and
the liquid-repellent protruding portion is also formed between the frame-shaped liquid-philic protruding portions separated into two in the liquid-repellent protruding portion formation step.

14-17. (canceled)

18. An electro-optical device including at least one electro-optical element and a sealing film, the sealing film sealing the electro-optical element on a support body, the sealing film including an organic layer obtained by curing an ink material, a first inorganic layer, and a second inorganic layer, the first inorganic layer and the second inorganic layer sandwiching the organic layer, the electro-optical device comprising:
a plurality of protruding portions surrounding the organic layer and having a frame shape,
wherein the protruding portions include a liquid-philic protruding portion having a surface having liquid-philic properties to the ink material and a liquid-repellent protruding portion having a surface having liquid-repellent properties to the ink material, and
the liquid-repellent protruding portion surrounds the liquid-philic protruding portion, at least a part of the liquid-philic protruding portion being located inside the liquid-repellent protruding portion.

19. The electro-optical device according to claim 18,
wherein the first inorganic layer has a surface having liquid-philic properties to the ink material,
the liquid-philic protruding portion is formed of a frame-shaped bank covered with the first inorganic layer,
the liquid-repellent protruding portion is also provided on the first inorganic layer, and
the second inorganic layer covers the organic layer, the liquid-philic protruding portion, and the liquid-repellent protruding portion.

20. The electro-optical device according to claim 19,
wherein the liquid-repellent protruding portion surrounds the liquid-philic protruding portion at a distance from the liquid-philic protruding portion on the outside of the liquid-philic protruding portion.

21. The electro-optical device according to claim 19,
wherein the liquid-repellent protruding portion is provided on the liquid-philic protruding portion formed of the frame-shaped bank covered with the first inorganic layer, a part of the liquid-philic protruding portion being exposed in a plan view.

22. The electro-optical device according to claim 21,
wherein the frame-shaped bank includes a recessed portion having a frame shape in a plan view in an upper face,
the liquid-philic protruding portion includes a recessed portion having a frame shape in a plan view in an upper face, a surface of the recessed portion in the frame-shaped bank being covered with the first inorganic layer, and
the liquid-repellent protruding portion is provided in the recessed portion in the liquid-philic protruding portion.

23. The electro-optical device according to claim 19,
wherein the frame-shaped bank includes two banks separated so as to have a double-frame shape,
the liquid-philic protruding portion includes two frame-shaped liquid-philic protruding portions separated so as to have a double-frame shape by covering a surface of the frame-shaped bank with the first inorganic layer, and
the liquid-repellent protruding portion is provided between the frame-shaped liquid-philic protruding portions separated into two.

24. The electro-optical device according to claim 18,
wherein the first inorganic layer and the liquid-philic protruding portion each have a surface having liquid-philic properties to the ink material,
the liquid-philic protruding portion and the liquid-repellent protruding portion are provided on the first inorganic layer, and
the second inorganic layer covers the organic layer, the liquid-philic protruding portion, and the liquid-repellent protruding portion.

25. The electro-optical device according to claim 18,
wherein the liquid-repellent protruding portion surrounds the liquid-philic protruding portion at a distance from the liquid-philic protruding portion on the outside of the liquid-philic protruding portion.

26. The electro-optical device according to claim 18,
wherein the liquid-philic protruding portion is formed of frame-shaped liquid-philic protruding portions being separated into two and having a double-frame shape, and
the liquid-repellent protruding portion is provided between the frame-shaped liquid-philic protruding portions separated into two.

27. The electro-optical device according to claim 18,
wherein the first inorganic layer and the liquid-philic protruding portion each have a surface having liquid-philic properties to the ink material,
the liquid-philic protruding portion is provided on the first inorganic layer,
the liquid-repellent protruding portion is provided on the liquid-philic protruding portion, a part of the liquid-philic protruding portion being exposed in a plan view, and
the second inorganic layer covers the organic layer, the liquid-philic protruding portion, and the liquid-repellent protruding portion.

28. The electro-optical device according to claim 27,
wherein the liquid-philic protruding portion includes a recessed portion having a frame shape in a plan view in an upper face, and
the liquid-repellent protruding portion is provided in the recessed portion.
